(19) United States
(12) Patent Application Publication
(10) Pub. No.: US 2024/0311676 A1
(43) Pub. Date: Sep. 19, 2024

(54) Performing Parametric Dissipation Operations in a Quantum Computing System

(71) Applicant: Rigetti & Co, LLC, Berkeley, CA (US)

(72) Inventor: Matthew J. Reagor, San Rafael, CA (US)

(73) Assignee: Rigetti & Co, LLC, Berkeley, CA (US)

(21) Appl. No.: 18/633,630

(22) Filed: Apr. 12, 2024

Related U.S. Application Data
(63) Continuation of application No. PCT/US2022/046586, filed on Oct. 13, 2022.
(60) Provisional application No. 63/255,268, filed on Oct. 13, 2021.

(51) Int. Cl. G06N 10/40

(52) U.S. Cl. CPC G06N 10/40

(57) ABSTRACT

In a general aspect, parametric dissipation operations are performed in a quantum computing system. In some implementations, a method includes executing a computer program in a computer system. Executing the computer program includes applying a quantum logic gate associated with a unitary operation to qubits defined by qubit devices on a quantum processing unit; obtaining an estimated value of a dissipation rate parameter; applying a parametric dissipation operation to one or more of the qubit devices; and measuring a state of one or more of the qubit devices. The parametric dissipation operation has a programmable dissipation rate that is controlled by the estimated value of the dissipation rate parameter; and the parametric dissipation operation is applied separately from the quantum logic gate.

### CROSS-REFERENCE TO RELATED APPLICATIONS

This application claims priority to U.S. Provisional Patent Application No. 63/255,268, filed Oct. 13, 2021, entitled “Variational Quantum Ansatz with Engineered Dissipation.” The above-referenced priority document is incorporated herein by reference in its entirety.

### TECHNICAL FIELD

The following description relates to performing parametric dissipation operations in a quantum computing system.

### BACKGROUND

Quantum computers can perform computational tasks by storing and processing information within quantum states of quantum systems. For example, qubits (i.e., quantum bits) can be stored in, and represented by, an effective two-level sub-manifold of a quantum coherent physical system. A variety of physical systems have been proposed for quantum computing applications. Examples include superconducting circuits, trapped ions, spin systems, and others.

### BRIEF DESCRIPTION OF THE DRAWINGS

FIG. 1 is a block diagram of an example computing environment.

FIG. 2 is a flow chart showing aspects of an example process.

FIG. 3A is a block diagram showing aspects of an example quantum logic circuit.

FIG. 3B is a block diagram showing aspects of an example quantum logic circuit.

FIG. 4 is a schematic diagram showing aspects of an example variational quantum algorithm.

FIG. 5 is a block diagram showing aspects of an example quantum computing system.

FIG. 6 is a schematic diagram showing aspects of an example quantum computing system.

FIG. 7A is a circuit diagram showing aspects of an example equivalent circuit of an example superconducting quantum processing unit.

FIG. 7B is a circuit diagram showing an example equivalent circuit of an example superconducting quantum processing unit.

### DETAILED DESCRIPTION

In some aspects of what is described here, a parametric dissipation operation in a computer program is performed in a quantum computing system. The computer program includes a quantum logic gate associated with a unitary operation. The quantum logic gate and the parametric dissipation operation are applied to quantum circuit devices of a quantum processing unit in the quantum computing system. In some implementations, the quantum logic gate and the parametric dissipative operation are executed separately and independently on a quantum processing unit. In other words, the quantum logic gate and the parametric dissipative operation are not simultaneously applied to the same qubits defined by the same qubit devices.

In some implementations, the computer program received by a quantum computing system includes unitary operations and a parameterized dissipation process. The unitary operation can be decomposed or compiled into a sequence of native quantum logic gates; and the parameterized dissipation process can be decomposed or compiled into a sequence of parametric dissipation operations, each of which is defined by a dissipation rate parameter. The native quantum logic gates and the parametric dissipation operations are specifically generated according to a particular quantum processing unit where the computer program is executed. A parameterized dissipation process can be performed on a quantum processing unit by executing the sequence of parametric dissipation operations on quantum circuit devices of the quantum processing unit. In some instances, the one or more parametric dissipation operations can be directly accessed and added to a native computer program by the user.

In some implementations, a parameterized dissipation process can be used to construct complex initial states and tailor initial states to improve performance of a computer program. A parameterized dissipation process in a computer program can be used to stabilize Fock states, cat states, and other quantum states. The target state prepared by a parameterized dissipation process can be robust to other sources of noise. In some instances, open quantum systems support quantum phase transitions that have richer dynamics than their unitary counterparts.

In some implementations, the systems and techniques described here can provide technical advantages and improvements. The methods and techniques presented here enables encoding some trainable parameters into parameterized dissipation process in addition to parametric quantum logic gates. The methods and techniques presented here increase robustness to noise and exploit the richer dynamics of open quantum systems, directly within a quantum circuit ansatz. The methods and techniques presented here closely resemble some applications of quantum simulation and represent a powerful extension to universal gate model quantum computers. The methods and techniques presented here make use of multi-photon processes on a superconducting qubit processor. Orchestrating the processor with this method allows to perform a target computational model. Universality on the processor can be maintained through standard gate-sets. Thus, these techniques augment the capabilities of a processor. Indeed, at least one of these schemes is intended to be compatible with the current generation of quantum computing hardware, such as superconducting integrated circuit-based quantum processor systems. In some cases, a combination of these and potentially other advantages and improvements may be obtained.

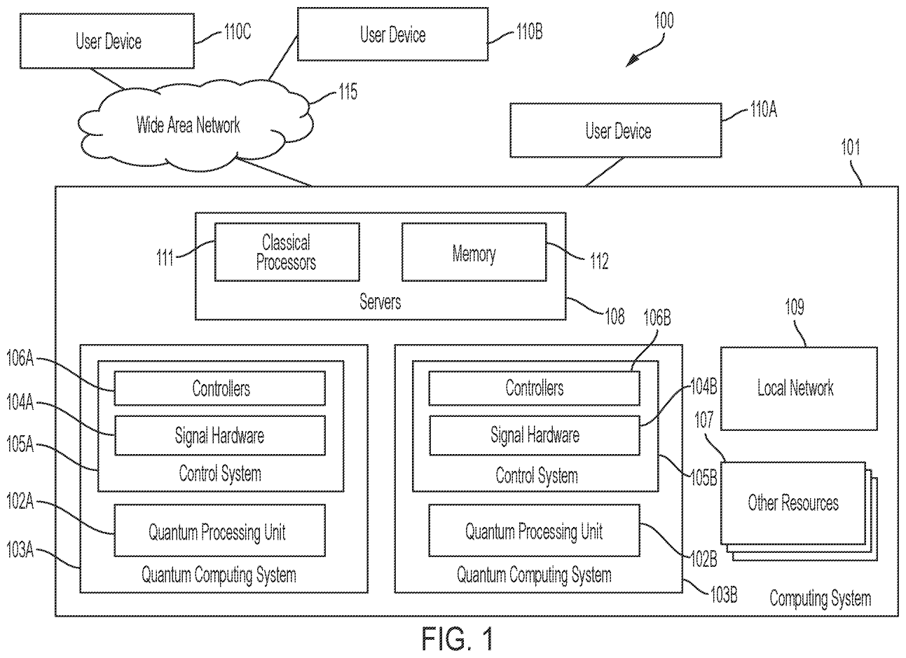

FIG. 1 is a block diagram of an example computing environment 100. The example computing environment 100 shown in FIG. 1 includes a computing system 101 and user devices 110A, 110B, 110C. A computing environment may include additional or different features, and the components of a computing environment may operate as described with respect to FIG. 1 or in another manner.

The example computing system 101 includes classical and quantum computing resources and exposes their functionality to the user devices 110A, 110B, 110C (referred to collectively as “user devices 110”). The computing system 101 shown in FIG. 1 includes one or more servers 108, quantum computing systems 103A, 103B, a local network 109, and other resources 107. The computing system 101 may also include one or more user devices (e.g., the user device 110A) as well as other features and components. A computing system may include additional or different features, and the components of a computing system may operate as described with respect to FIG. 1 or in another manner.

The example computing system 101 can provide services to the user devices 110, for example, as a cloud-based or remote-accessed computer system, as a distributed computing resource, as a supercomputer, or another type of high-performance computing resource, or in another manner. The computing system 101 or the user devices 110 may also have access to one or more other quantum computing systems (e.g., quantum computing resources that are accessible through the wide area network 115, the local network 109, or otherwise).

The user devices 110 shown in FIG. 1 may include one or more classical processors, memory, user interfaces, communication interfaces, and other components. For instance, the user devices 110 may be implemented as laptop computers, desktop computers, smartphones, tablets, or other types of computer devices. In the example shown in FIG. 1, to access computing resources of the computing system 101, the user devices 110 send information (e.g., programs, instructions, commands, requests, input data, etc.) to the servers 108; and in response, the user devices 110 receive information (e.g., application data, output data, prompts, alerts, notifications, results, etc.) from the servers 108. The user devices 110 may access services of the computing system 101 in another manner, and the computing system 101 may expose computing resources in another manner.

In the example shown in FIG. 1, the local user device 110A operates in a local environment with the servers 108 and other elements of the computing system 101. For instance, the user device 110A may be co-located with (e.g., located within 0.5 to 1 km of) the servers 108 and possibly other elements of the computing system 101. As shown in FIG. 1, the user device 110A communicates with the servers 108 through a local data connection.

The local data connection in FIG. 1 is provided by the local network 109. For example, some or all of the servers 108, the user device 110A, the quantum computing systems 103A, 103B, and the other resources 107 may communicate with each other through the local network 109. In some implementations, the local network 109 operates as a communication channel that provides one or more low-latency communication pathways from the server 108 to the quantum computer systems 103A, 103B (or to one or more of the elements of the quantum computer systems 103A, 103B). The local network 109 can be implemented, for instance, as a wired or wireless Local Area Network, an Ethernet connection, or another type of wired or wireless connection. The local network 109 may include one or more wired or wireless routers, wireless access points (WAPs), wireless mesh nodes, switches, high-speed cables, or a combination of these and other types of local network hardware elements. In some cases, the local network 109 includes a software-defined network that provides communication among virtual resources, for example, among an array of virtual machines operating on the server 108 and possibly elsewhere.

In the example shown in FIG. 1, the remote user devices 110B, 110C operate remote from the servers 108 and other elements of the computing system 101. For instance, the user devices 110B, 110C may be located at a remote distance (e.g., more than 1 km, 10 km, 100 km, 1,000 km, 10,000 km, or farther) from the servers 108 and possibly other elements of the computing system 101. As shown in FIG. 1, each of the user devices 110B, 110C communicates with the servers 108 through a remote data connection.

The remote data connection in FIG. 1 is provided by a wide area network 115, which may include, for example, the Internet or another type of wide area communication network. In some cases, remote user devices use another type of remote data connection (e.g., satellite-based connections, a cellular network, a virtual private network, etc.) to access the servers 108. The wide area network 115 may include one or more internet servers, firewalls, service hubs, base stations, or a combination of these and other types of remote networking elements. Generally, the computing environment 100 can be accessible to any number of remote user devices.

The example servers 108 shown in FIG. 1 can manage interaction with the user devices 110 and utilization of the quantum and classical computing resources in the computing system 101. For example, based on information from the user devices 110, the servers 108 may delegate computational tasks to the quantum computing systems 103A, 103B, and the other resources 107; the servers 108 can then send information to the user devices 110 based on output data from the computational tasks performed by the quantum computing systems 103A, 103B, and the other resources 107.

As shown in FIG. 1, the servers 108 are classical computing resources that include classical processors 111 and memory 112. The servers 108 may also include one or more communication interfaces that allow the servers to communicate via the local network 109, the wide area network 115, and possibly other channels. In some implementations, the servers 108 may include a host server, an application server, a virtual server, or a combination of these and other types of servers. The servers 108 may include additional or different features; and may operate as described with respect to FIG. 1 or in another manner.

The classical processors 111 can include various kinds of apparatus, devices, and machines for processing data, including, by way of example, a microprocessor, a central processing unit (CPU), a graphics processing unit (GPU), an FPGA (field programmable gate array), an ASIC (application specific integrated circuit), or combinations of these. The memory 112 can include, for example, a random-access memory (RAM), a storage device (e.g., a writable read-only memory (ROM) or others), a hard disk, or another type of storage medium. The memory 112 can include various forms of volatile or non-volatile memory, media, and memory devices, etc.

Each of the example quantum computing systems 103A, 103B operates as a quantum computing resource in the computing system 101. The other resources 107 may include additional quantum computing resources (e.g., quantum computing systems, quantum virtual machines (QVMs), or quantum simulators) as well as classical (non-quantum) computing resources such as, for example, digital microprocessors, specialized co-processor units (e.g., graphics processing units (GPUs), cryptographic co-processors, etc.), special purpose logic circuitry (e.g., field programmable gate arrays (FPGAs), application-specific integrated circuits (ASICs), etc.), systems-on-chips (SoCs), etc., or combinations of these and other types of computing modules.

In some implementations, the servers 108 generate programs, identify appropriate computing resources (e.g., a QPU or QVM) in the computing system 101 to execute the programs, and send the programs to the identified resources for execution. For example, the servers 108 may send programs to the quantum computing system 103A, the quantum computing system 103B, or any of the other resources 107. The programs may include classical programs, quantum programs, hybrid classical/quantum programs, and may include any type of function, code, data, instruction set, etc.

In some instances, programs can be formatted as source code that can be rendered in human-readable form (e.g., as text) and can be compiled, for example, by a compiler running on the servers 108, on the quantum computing systems 103, or elsewhere. In some instances, programs can be formatted as compiled code, such as, for example, binary code (e.g., machine-level instructions) that can be executed directly by a computing resource. Each program may include instructions corresponding to computational tasks that, when performed by an appropriate computing resource, generate output data based on input data. For example, a program can include instructions formatted for a quantum computer system, a quantum virtual machine, a digital microprocessor, co-processor or other classical data processing apparatus, or another type of computing resource.

In some cases, a program may be expressed in a hardware-independent format. For example, quantum machine instructions may be provided in a quantum instruction language such as Quil, described in the publication “A Practical Quantum Instruction Set Architecture,” arXiv:1608.03355v2, dated Feb. 17, 2017, or another quantum instruction language. For instance, the quantum machine instructions may be written in a format that can be executed by a broad range of quantum processing units or quantum virtual machines. In some cases, a program may be expressed in high-level terms of quantum logic gates or quantum programs, in lower-level terms of fundamental qubit rotations and controlled rotations, or in another form. In some cases, a program may be expressed in terms of control signals (e.g., pulse sequences, delays, etc.) and parameters for the control signals (e.g., frequencies, phases, durations, channels, etc.). In some cases, a program may be expressed in another form or format.

In some cases, a source quantum program is provided as, or converted to, a native quantum program that contains only native quantum logic gates for a given quantum processing unit. The native quantum logic gates for a quantum processing unit are the quantum logic gates that can be directly executed on the quantum processing unit. For instance, the hardware of a quantum processing unit may naturally provide only certain classes of operations, and the quantum processing unit may define an instruction set architecture that permits only a limited subset of the quantum logic gates in a larger library of quantum machine instructions. As an example, the quantum processing unit 102A may require quantum logic gate operators that lie in RZ(θ), RX(k*π/2), CZ and XY; and the quantum processing unit 102A may require quantum logic gates that act on physically available hardware (e.g., single-qubit gates that act on live qubits, or two-qubit gates that act on neighboring qubits). In this example, a gate is considered native if it is of the form of a single qubit Z-rotation (RZ(θ)) for any value of the rotation angle θ; a single qubit X-rotation (RX(k*π/2)) for any integer (k) number of π/2 rotations; a two-qubit controlled-Z gate (CZ) on a pair of qubits participating in a qubit-qubit interaction; or a two-qubit XY gate (XY) on a pair of qubits participating in a qubit-qubit interaction. In some contexts, it is desirable to write quantum programs that are not tied to a specific set of gates or instruction set architecture (e.g., to allow more portable code). Accordingly, the servers 108 may include a compiler that translates arbitrary quantum programs to native quantum programs (e.g., Quil to native Quil), which express the same quantum computing process in terms of the native gate set.

In some implementations, the servers 108 include one or more compilers that convert programs between formats. For example, the servers 108 may include a compiler that converts hardware-independent instructions to binary programs for execution by the quantum computing systems 103A, 103B. In some cases, a compiler can compile a program to a format that targets a specific quantum resource in the computer system 101. For example, a compiler may generate a different binary program (e.g., from the same source code) depending on whether the program is to be executed by the quantum computing system 103A or the quantum computing system 103B.

In some cases, a compiler generates a partial binary program that can be updated, for example, based on specific parameters. For instance, if a quantum program is to be executed iteratively on a quantum computing system with varying parameters on each iteration, the compiler may generate the binary program in a format that can be updated with specific parameter values at runtime (e.g., based on feedback from a prior iteration, or otherwise). In some cases, a compiler generates a full binary program that does not need to be updated or otherwise modified for execution.

In some implementations, the servers 108 generate a schedule for executing programs, allocate computing resources in the computing system 101 according to the schedule, and delegate the programs to the allocated computing resources. The servers 108 can receive, from each computing resource, output data from the execution of each program. Based on the output data, the servers 108 may generate additional programs that are then added to the schedule, output data that is provided back to a user device 110, or perform another type of action.

In some implementations, all or part of the computing environment operates as a cloud-based quantum computing (QC) environment, and the servers 108 operate as a host system for the cloud-based QC environment. The cloud-based QC environment may include software elements that operate on both the user devices 110 and the computer system 101 and interact with each other over the wide area network 115. For example, the cloud-based QC environment may provide a remote user interface, for example, through a browser or another type of application on the user devices 110. The remote user interface may include, for example, a graphical user interface or another type of user interface that obtains input provided by a user of the cloud-based QC environment. In some cases the remote user interface includes, or has access to, one or more application programming interfaces (APIs), command line interfaces, graphical user interfaces, or other elements that expose the services of the computer system 101 to the user devices 110.

In some cases, the cloud-based QC environment may be deployed in a “serverless” computing architecture. For instance, the cloud-based QC environment may provide on-demand access to a shared pool of configurable computing resources (e.g., networks, servers, storage, applications, services, quantum computing resources, classical computing resources, etc.) that can be provisioned for requests from user devices 110. Moreover, the cloud-based computing systems 104 may include or utilize other types of computing resources, such as, for example, edge computing, fog computing, etc.

In an example implementation of a cloud-based QC environment, the servers 108 may operate as a cloud provider that dynamically manages the allocation and provisioning of physical computing resources (e.g., GPUs, CPUs, QPUs, etc.). Accordingly, the servers 108 may provide services by defining virtualized resources for each user account. For instance, the virtualized resources may be formatted as virtual machine images, virtual machines, containers, or virtualized resources that can be provisioned for a user account and configured by a user. In some cases, the cloud-based QC environment is implemented using a resource such as, for example, OPENSTACK®. OPENSTACK® is an example of a software platform for cloud-based computing, which can be used to provide virtual servers and other virtual computing resources for users.

In some cases, the server 108 stores quantum machine images (QMI) for each user account. A quantum machine image may operate as a virtual computing resource for users of the cloud-based QC environment. For example, a QMI can provide a virtualized development and execution environment to develop and run programs (e.g., quantum programs or hybrid classical/quantum programs). When a QMI operates on the server 108, the QMI may engage either of the quantum processing units 102A, 102B, and interact with a remote user device (110B or 110C) to provide a user programming environment. The QMI may operate in close physical proximity to, and have a low-latency communication link with, the quantum computing systems 103A, 103B. In some implementations, remote user devices connect with QMIs operating on the servers 108 through secure shell (SSH) or other protocols over the wide area network 115.

In some implementations, all or part of the computing system 101 operates as a hybrid computing environment. For example, quantum programs can be formatted as hybrid classical/quantum programs that include instructions for execution by one or more quantum computing resources and instructions for execution by one or more classical resources. The servers 108 can allocate quantum and classical computing resources in the hybrid computing environment, and delegate programs to the allocated computing resources for execution. The quantum computing resources in the hybrid environment may include, for example, one or more quantum processing units (QPUs), one or more quantum virtual machines (QVMs), one or more quantum simulators, or possibly other types of quantum resources. The classical computing resources in the hybrid environment may include, for example, one or more digital microprocessors, one or more specialized co-processor units (e.g., graphics processing units (GPUs), cryptographic co-processors, etc.), special purpose logic circuitry (e.g., field programmable gate arrays (FPGAs), application-specific integrated circuits (ASICs), etc.), systems-on-chips (SoCs), or other types of computing modules.

In some cases, the servers 108 can select the type of computing resource (e.g., quantum or classical) to execute an individual program, or part of a program, in the computing system 101. For example, the servers 108 may select a particular quantum processing unit (QPU) or other computing resource based on availability of the resource, speed of the resource, information or state capacity of the resource, a performance metric (e.g., process fidelity) of the resource, or based on a combination of these and other factors. In some cases, the servers 108 can perform load balancing, resource testing and calibration, and other types of operations to improve or optimize computing performance.

Each of the example quantum computing systems 103A, 103B shown in FIG. 1 can perform quantum computational tasks by executing quantum machine instructions (e.g., a binary program compiled for the quantum computing system). In some implementations, a quantum computing system can perform quantum computation by storing and manipulating information within quantum states of a composite quantum system. For example, qubits (i.e., quantum bits) can be stored in, and represented by, an effective two-level sub-manifold of a quantum coherent physical system. In some instances, quantum logic can be executed in a manner that allows large-scale entanglement within the quantum system. Control signals can manipulate the quantum states of individual qubits and the joint states of multiple qubits. In some instances, information can be read out from the composite quantum system by measuring the quantum states of the qubits. In some implementations, the quantum states of the qubits are read out by measuring the transmitted or reflected signal from auxiliary quantum devices that are coupled to individual qubits.

In some implementations, a quantum computing system can operate using gate-based models for quantum computing. For example, the qubits can be initialized in an initial state, and a quantum logic circuit comprised of a series of quantum logic gates can be applied to transform the qubits and extract measurements representing the output of the quantum computation. Individual qubits may be controlled by single-qubit quantum logic gates, and pairs of qubits may be controlled by two-qubit quantum logic gates (e.g., entangling gates that are capable of generating entanglement between the pair of qubits). In some implementations, a quantum computing system can operate using adiabatic or annealing models for quantum computing. For instance, the qubits can be initialized in an initial state, and the controlling Hamiltonian can be transformed adiabatically by adjusting control parameters to another state that can be measured to obtain an output of the quantum computation.

In some models, fault-tolerance can be achieved by applying a set of high-fidelity control and measurement operations to the qubits. For example, quantum error correcting schemes can be deployed to achieve fault-tolerant quantum computation. Other computational regimes may be used; for example, quantum computing systems may operate in non-fault-tolerant regimes. In some implementations, a quantum computing system is constructed and operated according to a scalable quantum computing architecture. For example, in some cases, the architecture can be scaled to a large number of qubits to achieve large-scale general purpose coherent quantum computing. Other architectures may be used; for example, quantum computing systems may operate in small-scale or non-scalable architectures.

The example quantum computing system 103A shown in FIG. 1 includes a quantum processing unit 102A and a control system 105A, which controls the operation of the quantum processing unit 102A. Similarly, the example quantum computing system 103B includes a quantum processing unit 102B and a control system 105B, which controls the operation of a quantum processing unit 102B. A quantum computing system may include additional or different features, and the components of a quantum computing system may operate as described with respect to FIG. 1 or in another manner.

In some instances, all or part of the quantum processing unit 102A functions as a quantum processor, a quantum memory, or another type of subsystem. In some examples, the quantum processing unit 102A includes a quantum circuit system. The quantum circuit system may include qubit devices, readout devices, and possibly other devices that are used to store and process quantum information. In some cases, the quantum processing unit 102A includes a superconducting circuit, and the qubit devices are implemented as circuit devices that include Josephson junctions, for example, in superconducting quantum interference device (SQUID) loops or other arrangements, and are controlled by radio-frequency signals, microwave signals, and bias signals delivered to the quantum processing unit 102A. In some cases, the quantum processing unit 102A includes an ion trap system, and the qubit devices are implemented as trapped ions controlled by optical signals delivered to the quantum processing unit 102A. In some cases, the quantum processing unit 102A includes a spin system, and the qubit devices are implemented as nuclear or electron spins controlled by microwave or radio-frequency signals delivered to the quantum processing unit 102A. The quantum processing unit 102A may be implemented based on another physical modality of quantum computing.

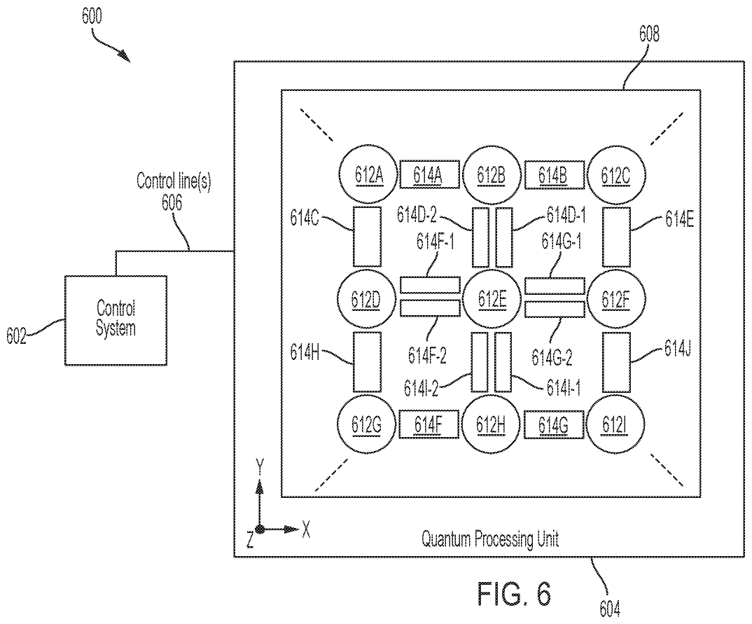

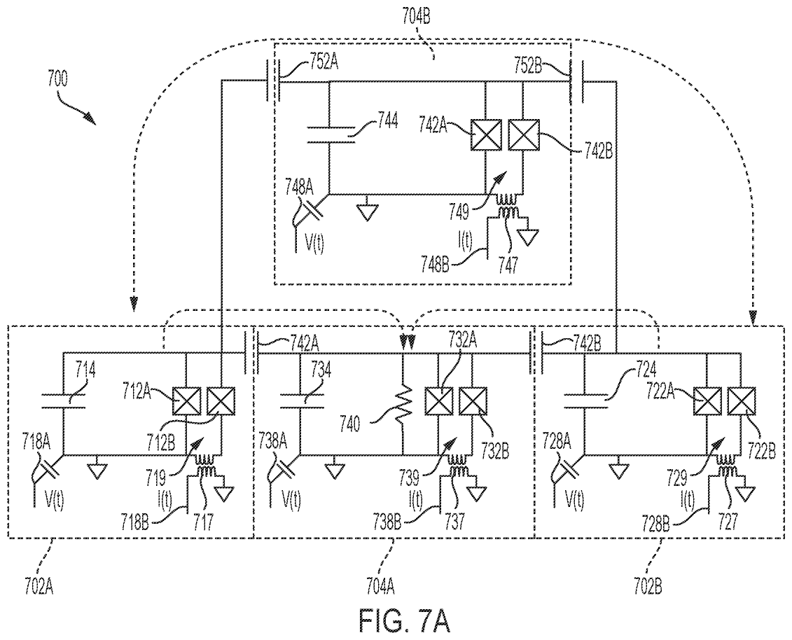

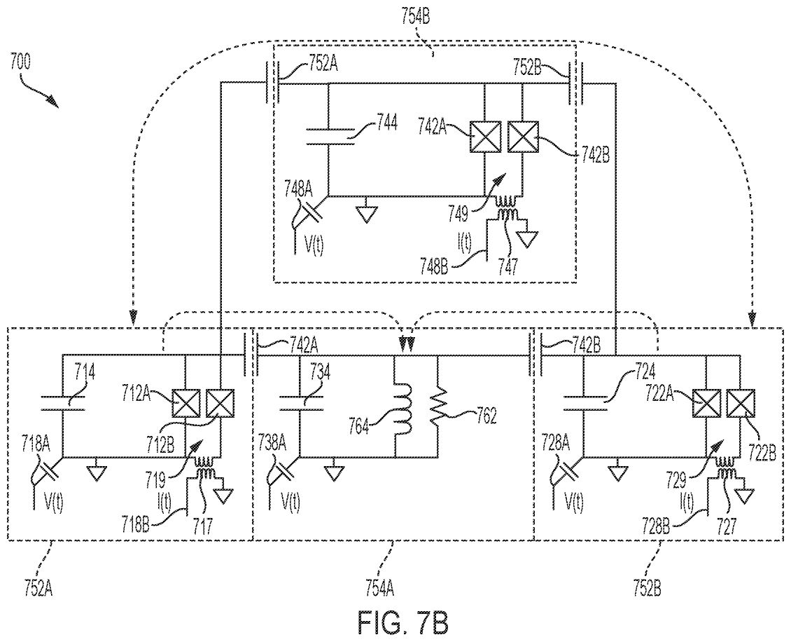

In some instances, the quantum processing unit 102A, 102B includes one or more dissipative coupler devices. A dissipative coupler device is communicably coupled to and associated with one or more qubit devices to control dissipation of the respective one or more coupled qubit devices. A qubit defined by a qubit device can be dissipated through an associated dissipative coupler device. In some implementations, a dissipative coupler device is a lossy device which has a finite dissipation factor allowing for an irreversible process of energy dissipation from the associated qubit device to the dissipative coupler device. A dissipative coupler device may be communicably coupled to a qubit device capacitively, inductively or in another manner. The dissipation rate of the qubit device can be controlled via the dissipative coupler device, for example, by directly tuning the dissipation factor, the effective coupling between the dissipative coupler device and the qubit device, or in another manner. A dissipative coupler device can be operated by the control system to be activated when a parametric dissipation operation is performed on the qubit device and deactivated when a quantum logic gate is applied to the qubit device. In some instances, a dissipative coupler device may be implemented as the dissipative coupler device 614, 704A, 754A in FIGS. 6, 7A, 7B or in another manner.

In some implementations, the example quantum processing unit 102A includes multiple quantum processor modules. For example, the quantum processing unit 102A may include a two-dimensional or three-dimensional array of quantum processor modules, and each quantum processor module may include an array of quantum circuit devices. In this case, the example quantum processing unit 102A is a modular quantum processing unit. In some cases, the quantum processor modules may be supported on a common substrate and may be connected through circuitry on the common substrate.

The quantum processing unit 102A may include, or may be deployed within, a controlled environment. The controlled environment can be provided, for example, by shielding equipment, cryogenic equipment, and other types of environmental control systems. In some examples, the components in the quantum processing unit 102A operate in a cryogenic temperature regime and are subject to very low electromagnetic and thermal noise. For example, magnetic shielding can be used to shield the system components from stray magnetic fields, optical shielding can be used to shield the system components from optical noise, and thermal shielding and cryogenic equipment can be used to maintain the system components at controlled temperature, etc.

In some implementations, the example quantum processing unit 102A can process quantum information by applying control signals to the quantum circuit devices in the quantum processing unit 102A. The control signals can be configured to encode information in the qubits, to process the information by performing quantum logic gates or other types of operations, or to extract information from the qubits. In some examples, the operations can be expressed as single-qubit quantum logic gates, two-qubit quantum logic gates, or other types of quantum logic gates that operate on one or more qubits. A quantum logic circuit, which includes a sequence of quantum logic gates, can be applied to the qubits to perform a quantum program. The quantum program may correspond to a computational task, a hardware test, a quantum error correction procedure, a quantum state distillation procedure, or a combination of these and other types of operations.

The example control system 105A includes controllers 106A and signal hardware 104A. Similarly, control system 105B includes controllers 106B and signal hardware 104B. All or part of the control systems 105A, 105B can operate in a room-temperature environment or another type of environment, which may be located near the respective quantum processing units 102A, 102B. In some cases, the control systems 105A, 105B include classical computers, signaling equipment (microwave, radio, optical, bias, etc.), electronic systems, vacuum control systems, refrigerant control systems, or other types of control systems that support operation of the quantum processing units 102A, 102B.

The control systems 105A, 105B may be implemented as distinct systems that operate independent of each other. In some cases, the control systems 105A, 105B may include one or more shared elements; for example, the control systems 105A, 105B may operate as a single control system that operates both quantum processing units 102A, 102B. Moreover, a single quantum computer system may include multiple quantum processing units, which may operate in the same controlled (e.g., cryogenic) environment or in separate environments.

The example signal hardware 104A includes components that communicate with the quantum processing unit 102A. The signal hardware 104A may include, for example, waveform generators, amplifiers, digitizers, high-frequency sources, DC sources, AC sources, cryogenic and on-chip signal generation devices, etc. The signal hardware may include additional or different features and components. In the example shown, components of the signal hardware 104A are adapted to interact with the quantum processing unit 102A. For example, the signal hardware 104A can be configured to operate in a particular frequency range, configured to generate and process signals in a particular format, or the hardware may be adapted in another manner.

In some instances, one or more components of the signal hardware 104A generate control signals, for example, based on control information from the controllers 106A. The control signals can be delivered to the quantum processing unit 102A during operation of the quantum computing system 103A. For instance, the signal hardware 104A may generate signals to implement quantum logic gates, readout operations, or other types of operations. As an example, the signal hardware 104A may include arbitrary waveform generators (AWGs) that generate electromagnetic waveforms (e.g., microwave or radio-frequency) or laser systems that generate optical waveforms. The waveforms or other types of signals generated by the signal hardware 104A can be delivered to devices in the quantum processing unit 102A to operate qubit devices, readout devices, bias devices, coupler devices, or other types of components in the quantum processing unit 102A.

In some instances, the signal hardware 104A receives and processes signals from the quantum processing unit 102A. The received signals can be generated by the execution of a quantum program on the quantum computing system 103A. For instance, the signal hardware 104A may receive signals from the devices in the quantum processing unit 102A in response to readout or other operations performed by the quantum processing unit 102A. Signals received from the quantum processing unit 102A can be mixed, digitized, filtered, or otherwise processed by the signal hardware 104A to extract information, and the information extracted can be provided to the controllers 106A or handled in another manner. In some examples, the signal hardware 104A may include a digitizer that digitizes electromagnetic waveforms (e.g., microwave or radio-frequency) or optical signals, and a digitized waveform can be delivered to the controllers 106A or to other signal hardware components. In some instances, the controllers 106A process the information from the signal hardware 104A and provide feedback to the signal hardware 104A; based on the feedback, the signal hardware 104A can in turn generate new control signals that are delivered to the quantum processing unit 102A.

In some implementations, the signal hardware 104A includes signal delivery hardware that interfaces with the quantum processing unit 102A. For example, the signal hardware 104A may include filters, attenuators, directional couplers, multiplexers, diplexers, bias components, signal channels, isolators, amplifiers, power dividers, and other types of components. In some instances, the signal delivery hardware performs preprocessing, signal conditioning, or other operations to the control signals to be delivered to the quantum processing unit 102A. In some instances, signal delivery hardware performs preprocessing, signal conditioning, or other operations on readout signals received from the quantum processing unit 102A.

The example controllers 106A communicate with the signal hardware 104A to control operation of the quantum computing system 103A. The controllers 106A may include classical computing hardware that directly interface with components of the signal hardware 104A. The example controllers 106A may include classical processors, memory, clocks, digital circuitry, analog circuitry, and other types of systems or subsystems. The classical processors may include one or more single-or multi-core microprocessors, digital electronic controllers, special purpose logic circuitry, e.g., an FPGA (field programmable gate array) or an ASIC (application specific integrated circuit), or other types of data processing apparatus. The memory may include any type of volatile or non-volatile memory or another type of computer storage medium. The controllers 106A may also include one or more communication interfaces that allow the controllers 106A to communicate via the local network 109 and possibly other channels. The controllers 106A may include additional or different features and components.

In some implementations, the controllers 106A include memory or other components that store quantum state information, for example, based on qubit readout operations performed by the quantum computing system 103A. For instance, the states of one or more qubits in the quantum processing unit 102A can be measured by qubit readout operations, and the measured state information can be stored in a cache or other type of memory system in or more of the controllers 106A. In some cases, the measured state information is subsequently used in the execution of a quantum program, a quantum error correction procedure, a quantum processing unit (QPU) calibration or testing procedure, or another type of quantum process.

In some implementations, the controllers 106A include memory or other components that store a quantum program containing quantum machine instructions for execution by the quantum computing system 103A. In some instances, the controllers 106A can interpret the quantum machine instructions and perform hardware-specific control operations according to the quantum machine instructions. For example, the controllers 106A may cause the signal hardware 104A to generate control signals that are delivered to the quantum processing unit 102A to execute the quantum machine instructions.

In some instances, the controllers 106A extract qubit state information from qubit readout signals, for example, to identify the quantum states of qubits in the quantum processing unit 102A or for other purposes. For example, the controllers may receive the qubit readout signals (e.g., in the form of analog waveforms) from the signal hardware 104A, digitize the qubit readout signals, and extract qubit state information from the digitized signals. In some cases, the controllers 106A compute measurement statistics based on qubit state information from multiple shots of a quantum program. For example, each shot may produce a bitstring representing qubit state measurements for a single execution of the quantum program, and a collection of bitstrings from multiple shots may be analyzed to compute quantum state probabilities.

In some implementations, the controllers 106A include one or more clocks that control the timing of operations. For example, operations performed by the controllers 106A may be scheduled for execution over a series of clock cycles, and clock signals from one or more clocks can be used to control the relative timing of each operation or groups of operations. In some implementations, the controllers 106A may include classical computer resources that perform some or all of the operations of the servers 108 described above. For example, the controllers 106A may operate a compiler to generate binary programs (e.g., full or partial binary programs) from source code; the controllers 106A may include an optimizer that performs classical computational tasks of a hybrid classical/quantum program; the controllers 106A may update binary programs (e.g., at runtime) to include new parameters based on an output of the optimizer, etc.

The other quantum computer system 103B and its components (e.g., the quantum processing unit 102B, the signal hardware 104B and controllers 106B) can be implemented as described above with respect to the quantum computer system 103A; in some cases, the quantum computer system 103B and its components may be implemented or may operate in another manner.

In some implementations, the quantum computer systems 103A, 103B are disparate systems that provide distinct modalities of quantum computation. For example, the computer system 101 may include both an adiabatic quantum computer system and a gate-based quantum computer system. As another example, the computer system 101 may include a superconducting circuit-based quantum computer system and an ion trap-based quantum computer system. In such cases, the computer system 101 may utilize each quantum computing system according to the type of quantum program that is being executed, according to availability or capacity, or based on other considerations.

In some cases, the control system 105 includes one or more digital computers or digital computing components that produce a control sequence, for instance, based on a quantum program. For example, a digital processor may convert a source quantum program (e.g., instructions written in the Quil programming language) to an instruction set for the native gate set or architecture of the quantum processing unit 102. The quantum program may be generated locally by compiling a user program, received from a remote system, or obtained in another manner.

In some implementations, the series of native quantum logic gates in a compiled quantum program includes one or more parametric gates. For instance, the series of native quantum logic gates may generally include any type of single-qubit parametric rotation, any type of two-qubit parametric interaction, a controlled (or a controlled-controlled) single-qubit parametric rotation, a controlled (or a controlled-controlled) two-qubit parametric interaction, or another type of parametric quantum logic gate. In some cases, the series of native quantum logic gates in the compiled quantum program also includes non-parametric gates.

In some aspects of operation, the compiler receives a source quantum program that includes a first quantum logic gate, for example, within a larger quantum logic circuit specified in the source quantum program. The compiler generates a native quantum program that corresponds to the source quantum program and is configured for a target quantum processing unit. In certain examples, the native quantum program is a binary quantum program formatted for execution by control electronics associated with the target quantum processing unit. In some cases, the native quantum program can be an updated version of the source quantum program, for example, that expresses the quantum logic circuit in terms of a native gate set of the target quantum processing unit. To generate the native quantum program, the compiler identifies a series of native quantum logic gates that are logically equivalent to the first quantum logic gate in the source quantum program (e.g., the series corresponds to the same unitary operation, up to a global phase). In some instances, the series of native quantum logic gates (in the native quantum program) are selected from the native gate set of the target quantum processing unit. In some instances, the compiler obtains the series of native quantum logic gates from a library of quantum logic circuits. In some examples, the compiler generates the series of native quantum logic gates by executing a parametric decomposition process. For example, an arbitrary two-qubit quantum logic gate in a source quantum program can be compiled with some fixed set of native entangling gates. Any arbitrary two-qubit quantum logic gate can be expressed with at most 3 controlled-Zs (CZs) or 3 iSWAPs in addition to single-qubit rotations.

In some implementations, the source quantum program may include one or more parameterized dissipation processes. In some instances, a parameterized dissipation process may be specified by the user when the source quantum program is generated. For example, the user may specify a stochastic effect that can be approximated and represented by the parameterized dissipation process. In certain instances, the user may specify other criteria and objectives for guiding the formation of a parameterized dissipation process in the source quantum program or the selection of parametric dissipative operations from a native dissipation operation set in the compilation process. A parametric dissipative operation, when applied to a qubit defined by a qubit device, controls the energy dissipation rate of the qubit of the qubit device. In other words, unlike quantum logic gates in an associated unitary operation, a parametric dissipative operation is an irreversible process. For example, the user may include target states, a target dissipation rate, or other criteria or objectives. In some implementations, the compiler selects and specifies quantum resources (e.g., the qubit devices 612 and coupler devices 614 in the superconducting quantum processing unit 604 in FIG. 6) where parametric dissipative operations are applied and quantum resources where the parametric dissipative operations are not applied. In some implementations, the compiler can compile a parameterized dissipation process into a sequence of parametric dissipation operations. In some instances, a user may select the sequence of parametric dissipation operations directly from the native dissipation operation set according to the available dissipation operations and their corresponding quantum hardware.

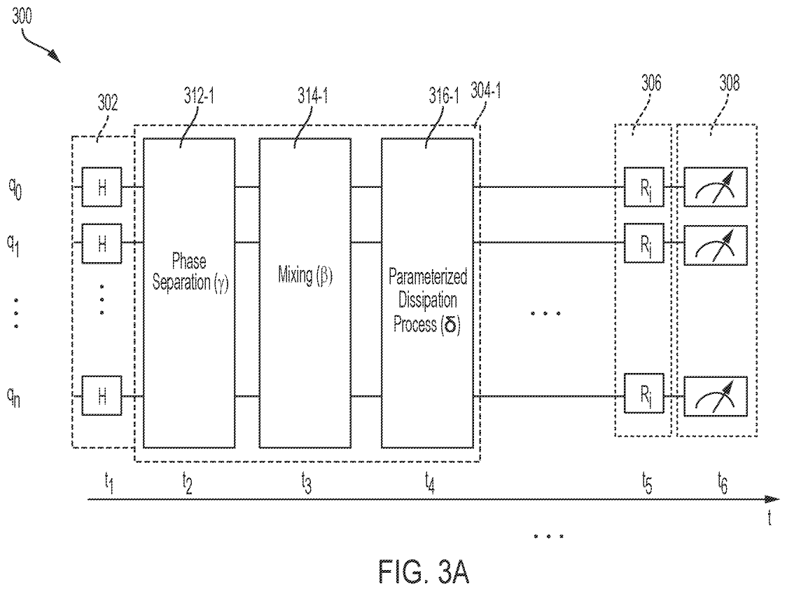

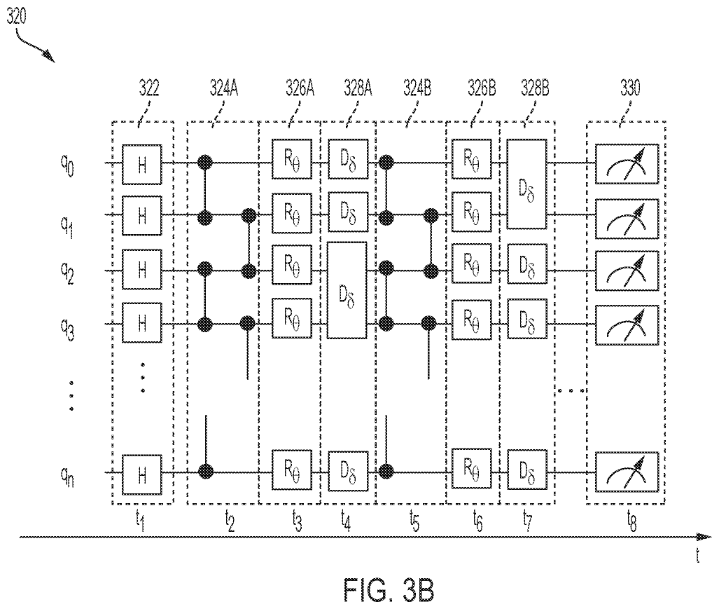

In some instances, the control system 105 can implement a device measurement process or calibration process on a quantum circuit device and interpret the measurements to extract device parameters. The device parameters can be physical attributes of the device, for example, the resonance frequency between the two lowest energy levels of a qubit. When a calibration process is used to determine control parameters for quantum logic gates and control parameters for parametric dissipation operations, initial values of the control parameters can be then determined by the control system 105 according to the device parameters. When a different set of qubits is selected, the initial values of the control parameters to operate quantum logic gates or parametric dissipative operations can be different. In some instances, a calibration process (e.g., the calibration process 306 in FIG. 3) to determine improved or optimal values of the control parameters (e.g., starting from the initial values of the control parameters as initial conditions) can be performed by operation of the control system 105. Accurate determination of the values of the control parameters can be important, for example, to enable operation of the quantum computing system 100 with a desired performance.

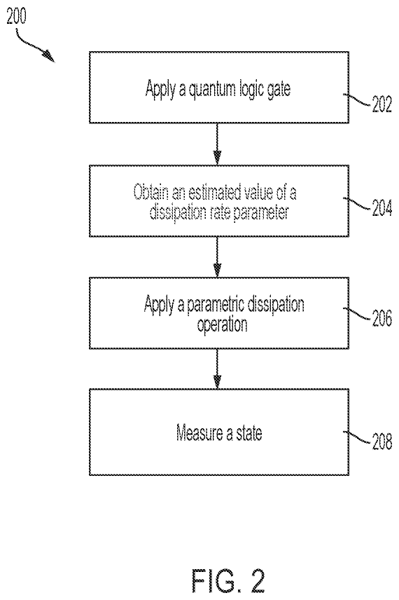

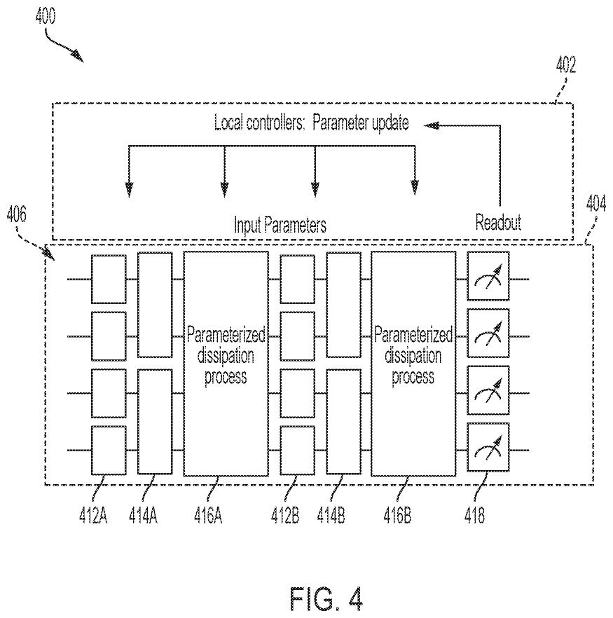

FIG. 2 is a flow chart showing aspects of an example process 200. The example process 200 can be used, for example, to execute a quantum program with a parameterized dissipation operation. For instance, the example process 200 can be used to execute a quantum program represented by the quantum logic circuit 300, 320 in FIGS. 3A-3B, by the variational quantum algorithm 400 in FIG. 4, or by another type of quantum program. The example process 200 may include additional or different operations, including operations performed by additional or different quantum circuit devices, and the operations may be performed in the order shown or in another order.

In some implementations, one or more operations in the example process 200 can be performed by a computer system, for instance, by a digital computer system having one or more digital processors (e.g., a microprocessor or other data processing apparatus) that execute instructions (e.g., instructions stored in a digital memory or other computer-readable medium), or by another type of digital, quantum or hybrid computer system. As an example, in some cases the quantum processing unit can be deployed as the quantum processing unit 102 shown in FIG. 1, and operations in the example process 200 shown in FIG. 2 can be initiated, executed, or controlled by one or more components of the control system 105 shown in FIG. 1. In some instances, the example process 200 may be performed on different quantum processor modalities, e.g., ion traps and atom simulators, which may support unitary operations via individual or global control fields, for instance microwave or optical drives that cause population to change between computational or non-computational states or cause phase to accumulate between some states relative to others.

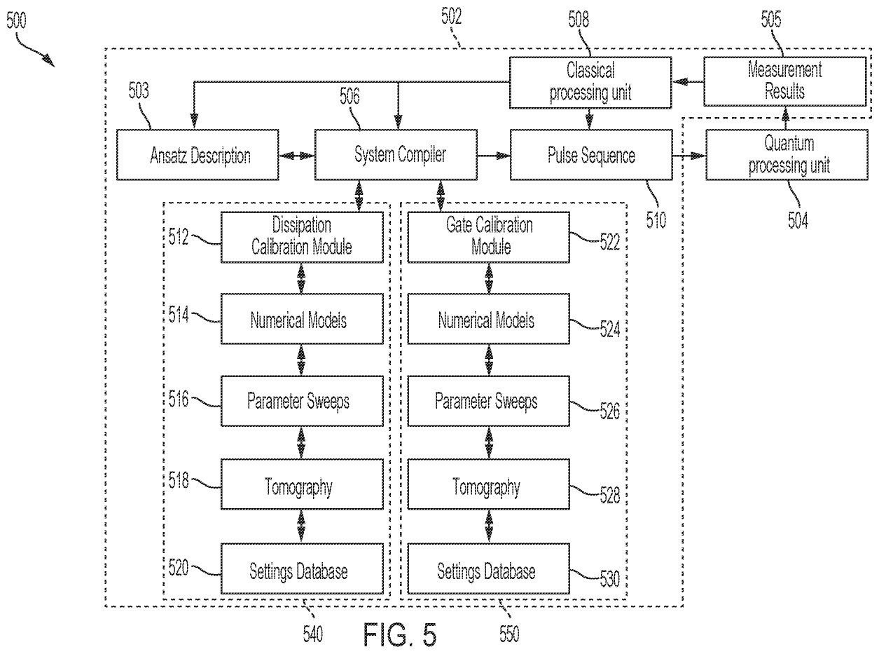

At 202, a quantum logic gate is applied to one or more qubits. The quantum logic gate is associated with a unitary operation. In some instances, the unitary operation is included in a quantum program which can be obtained by operation of a compiler (e.g., the system compiler 506 in FIG. 5) on a received quantum program (e.g., the ansatz description 503 in FIG. 5) from a user (e.g., a user program). A sequence of quantum logic gates in the quantum program before compilation can be converted to a sequence of native quantum logic gates in the quantum program after compilation. In some instances, the sequence of native quantum logic gates in the unitary operation can be applied to qubits defined by qubit devices in the quantum processing unit.

In some implementations, a quantum program can be represented, for example, as a quantum Hamiltonian, a quantum logic circuit with a sequence of quantum logic gates, a set of quantum machine instructions, or otherwise. The quantum program may correspond to a computational task, a hardware test, a quantum error correction procedure, a quantum state distillation procedure, or a combination of these and other types of operations. In some instances, a quantum program includes a first sequence of quantum logic gates, e.g., single-qubit quantum logic gates, two-qubit quantum logic gates, multi-qubit quantum logic gates, identity gates, and other quantum logic gates. In some instances, the quantum program can be an Quil program generated by a user device (e.g., the user device 110 as shown in FIG. 1), another computer resource outside the local environment of the quantum computer system 103, or in another manner; and received by a quantum computing system (e.g., the control system 105 of the quantum computing system 103 in FIG. 1).

In some instances, the received quantum program is compiled. In some implementations, the received quantum program is compiled according to the particular quantum computing system where the quantum program is to be executed. In this case, after compilation, the compiled quantum program includes native quantum logic gates that can be directly executed on quantum circuit devices in a quantum processing unit (e.g., the qubit devices 612 and the associated coupler devices 614 in the quantum processing unit 604 as shown in FIG. 6).

In some instances, a native gate set includes a set of native quantum logic gates that can be directly executed by the quantum processing unit. After a native gate set for the quantum processing unit is identified, a quantum logic gate in the first sequence of quantum logic gates (e.g., one or more parametric quantum logic gates) in the received quantum program can be converted, translated, or otherwise compiled into a native gate sequence with a second sequence of quantum logic gates. Each of the native quantum logic gates in a native gate sequence may be a parametric single-qubit rotation gate, a parametric two-qubit quantum logic gate, a parametric three-qubit quantum logic gate, or another quantum logic gate. In addition to the parametric quantum logic gates, a native gate set may include one or more non-parametric quantum logic gates. For example, a two-qubit quantum logic gate, e.g., CNOT gate, in a received quantum program from a user can be decomposed into several iSWAP gates or a CZ gate that can be directly executed on quantum circuit devices in a quantum processing unit. When the received quantum program before compilation includes one or more quantum logic gates, one or more native gate sequences can be formed, e.g., by parametric decomposition or in another manner. Generally, the one or more native gate sequences after compilation are quantum-logically equivalent to the respective one or more quantum logic gates in the received quantum program before compilation.

In some implementations, parametric dissipation operations are added to the quantum program programmatically, e.g., programed by a user, introduced by a compiler, or in another manner, that may occur between the one or more quantum logic gates and a qubit readout operation or qubit measurement operation. In some implementations, the received quantum program further includes one or more parameterized dissipation processes defined by a single parameter (e.g., the parameterized dissipation process 316 defined by the single parameter δ in FIG. 3). In this case, each of the one or more parameterized dissipation processes can be converted, translated, or otherwise compiled into a sequence of operations that are applied to one or more qubits defined by respective qubit devices. The sequence of operations includes one or more parametric dissipation operations and other control operations. Each of the one or more parametric dissipation operations is defined by a dissipation rate parameter. The sequence of operations is determined according to the topology and connectivity of qubit devices and available dissipative coupler devices associated with the qubit devices in a particular quantum computing system where the native quantum program is to be executed. For example, the one or more parametric dissipation operations includes one or more native single-qubit parametric dissipation operations, one or more native two-qubit parametric dissipation operations, and other native parametric dissipation operations that can be directly applied to qubits in the quantum computing system. In some instances, estimated values of the dissipation rate parameters of the one or more parametric dissipation operations in the sequence may be determined according to the target values of the parameters associated with the one or more parameterized dissipation processes.

In some instances, one or more native parametric dissipation operations can be directly selected, and configured by the user after the compiled native quantum program is generated. For example, after a native quantum program is generated, a user can modify the native quantum program to include one or more native parametric dissipation operations. In some instances, the one or more native parametric dissipation operations can be selected from a native dissipation operation set which includes information of native parametric dissipation operations available in a quantum processing unit on which the native quantum program is executed. In certain instances, the modified native quantum program which includes the one or more native parametric dissipation operations can be simulated, prior to be executed on the quantum processing unit. The user can further modify the estimated values of the dissipation rate parameters of the one or more native parametric dissipation operations according to some objectives or criteria. The objectives or criteria specified or expressed by the user in the source quantum program or after the formation of the compiled quantum program. For example, the objectives or criteria may include information or parameters that can be used to identify or determine target states of qubit devices after the parameterized dissipation process; a stochastic effect associated with the parameterized dissipation process, a target value of parameter defining the parameterized dissipation process, and other parameters. In certain examples, the information or parameters that can be used to determine the target states of qubit devices includes computational basis states. In some instances, the objectives and criteria can be used to guide the modification of the native quantum program by adding the one or more native parametric dissipation operations.

In certain instances, a user may separately submit a request for including a parameterized dissipation process to a quantum program. In this case, the quantum program may not include a parameterized dissipation process or may not specify a target value of the parameter of the parameterized dissipation process; and during a compilation process, the compiler may add or modify a sequence of native parametric dissipation operations as part of the native quantum program according to the request from the user. The request may include criteria or objectives of the parameterized dissipation process in the quantum program, for instance, a target state to prepare as a result of the computation. In this case, the sequence of native parametric dissipation operations may be determined according to the topology and connectivity of qubit devices and available dissipative coupler devices associated with the qubit devices in a particular quantum computing system where the native quantum program is to be executed. In some implementations, a user may also modify a native quantum program by removing parametric dissipative operations, adding parametric dissipative operations, modifying values of the dissipation rate parameters of parametric dissipative operations, or other type of modifications.

In some implementations, controlled dissipation of qubits can be added to the quantum logic circuit of the quantum program. For example, when the quantum program is associated with a quantum machine learning algorithm, the parametric dissipation process may be used during training to provide regularization, for instance as tunable dissipation interleaved with unitary operations, and associated dissipation rates may be constant during a single training epoch but may change, for example randomly, between training epochs, and for example, dissipation may be removed or a set of dissipation parameters that were trained may be used during inference. For another example, when the quantum program is associated with a hybrid variational quantum algorithm, the parametric dissipation process can be used to encode a cost function or constraint associated with the target application, for instance penalizing an undesired path through state space that may, for example, violate hard or soft constraints within the problem construction (e.g., Hamming weight of a bitstring solution). Deploying separate mechanisms for unitary evolution and dissipation may be used to provide more efficient training or quantum state evolution.

At 204, estimated values of dissipation rate parameters of the one or more parametric dissipation operations in the sequence are obtained. In some implementations, the estimated values of the dissipation rate parameters are obtained according to the target value of the parameter of the parameterized dissipation process specified by and received in the computer program. In some implementations, the estimated values of the dissipation rate parameters of the respective parameteric dissipation operations, which are logically equivalent to the parameterized dissipation process, are computed by operation of the compiler.

In some implementations, when the computer program is a hybrid classical-quantum program (e.g., the variational quantum program 400 in FIG. 4) comprising classical computing operations and quantum computing operations, executing the computer program in the computer system comprises executing the classical computing operations on at least one classical processing unit, and the estimated values of the dissipation rate parameters of the parametric dissipation operations are computed based on an output of the classical computing operations.

At 206, a parametric dissipation operation is applied. A parametric dissipation operation, which is defined by the estimated value of the dissipation rate parameter, is applied to one or more qubits defined by one or more respective qubit devices in a quantum processing unit. In some implementations, applying a parametric dissipation operation includes applying parametrically-controlled active manipulation of a dissipative environment that the one or more respective qubit devices are coupled to. By tunning the value of the dissipation rate parameter of a parametric dissipation operation, a dissipation rate on the qubits can be programmed and controlled by the parametric dissipation operation. In some implementations, when a parametric dissipation operation is applied, one or more control operations applied to other quantum circuit devices are also performed. For example, during a two-qubit parametric dissipation operation, the second coupler device 704B can be deactivated; and the control operations include communicating a control signal to deactivate the second coupler device 704B between the two qubit devices 702A, 702B.

For example, when the quantum processing unit is implemented as the superconducting quantum processing unit shown in FIGS. 7A-7B, the control operations for performing a parametric dissipation operation may include communicating coupler flux bias signals to the respective dissipative coupler devices. Coupler flux biases experienced by the respective dissipative coupler devices and thus the respective transition frequencies of the respective dissipative coupler devices can be controlled; and the effective coupling between the qubit device and the dissipative coupler device and programmable dissipation rates of the qubit devices can be achieved. Values of control parameters of control signals communicated to quantum circuit devices of the quantum processing unit for performing the parametric dissipation operations defined by the estimated values of the dissipation rate parameters can be determined through a calibration process (e.g., by operation of the dissipation calibration module 512 in FIG. 5).

In some implementations, a calibration process, for example, a dissipation calibration process by operation of the dissipation calibration module 512 in the control system 502 or a gate calibration process by operation of the gate calibration module 522 in the control system 502, is performed to determine control parameters of control signals for executing the native quantum program (e.g., the parametric dissipation operations and the parametric quantum logic gates) on a particular quantum processing unit. In some instances, device parameters of the designated quantum circuit devices where the native quantum program is executed can be obtained. For example, the device parameters of the qubit devices, the dissipative coupler devices, the non-dissipative coupler devices in the quantum processing unit are determined by performing a measurement or characterization process, a tune-up process, or another type of calibration process. In some instances, a measurement process can characterize a particular set of quantum circuit devices in the quantum processing unit for performing the native quantum program. In some instances, the device parameters may be predetermined using another process, which then can be stored and obtained in another manner. For example, a measurement process can be executed to characterize all the quantum circuit devices in a quantum processing unit to obtain the device parameters of each of the qubit devices and coupler devices in a device array, for example, once a quantum processor is cooled down.

In some instances, device parameters that can be used to characterize a tunable-frequency qubit device include a tunable range of transition frequencies. In certain examples, a tunable range of transition frequencies is defined by a maximal frequency value, e.g., the |0 [symbol] →|1 [symbol] transition frequency value at a magnetic flux of zero flux quantum applied to the tunable-frequency qubit device,

$${ω}_{01} ( Φ = 0 ) ≡ {ω}_{01}^{max} \qquad ( 1 )$$

and a minimum frequency value, e.g., the |0 [symbol] →|1 [symbol] transition frequency value at a magnetic flux of half-flux quantum,

$${ω}_{01} ( Φ = \frac{{Φ}_{0}}{2} ) ≡ {ω}_{01}^{min} \qquad ( 2 )$$

anharmonicity at the magnetic flux of zero flux quantum,

$$η ( Φ = 0 ) ≡ {η}^{max} \qquad ( 3 )$$

and the qubit flux bias Φ, e.g.,

$$Q = Q ( {ω}_{01}^{max} , {ω}_{01}^{min} , {η}^{max} , Φ ) \qquad ( 4 )$$

where Q represents a collection of device parameters that can be used to describe a qubit device. In some implementations, a maximal frequency value may be at a different magnetic flux. For example, a maximal frequency value may be at a value offset from a magnetic flux of zero flux quantum, a magnetic flux of half flux quantum, or another value.

In some implementations, the device parameters may include one or more of the device parameters of the tunable-frequency qubit device in the quantum processing unit. For example, device parameters, such as a maximum transition frequency ω₁₂^{max}, and the anharmonicity (η) at ω₁₂^{max}, can be used to characterize the qubit implementation beyond the lowest two states. In some instances, device parameters further include periodicity, coupling strengths, and other device parameters can be calibrated, measured, and stored, e.g., in a database of the memory 112 of the server 108. In certain instances, circuit parameters of circuit components in an equivalent circuit representing quantum circuit devices in the quantum processing unit can be calculated based on the device parameters.

In some examples, the transition frequency of a tunable-frequency qubit device or a tunable-frequency coupler device from the ground state |0 [symbol] to the first excited state |1 [symbol] is measured by using qubit spectroscopy. Ramsey interferometry can then be used to fine tune the value of the transition frequency obtained from the spectroscopic measurement. In some instances, the transition frequency can be measured at one or more reference values of the applied magnetic flux. For example, the transition frequency of a tunable-frequency qubit device can be measured at zero flux and one-half flux quantum; the tunable-frequency qubit devices may be measured under other flux conditions.

In some examples, after the transition frequencies of the tunable-frequency qubit device are obtained, qubit spectroscopy can be used to measure the transition frequency from the ground state |0 [symbol] to the second excited state |2 [symbol] which can be used to calculate the anharmonicity of the tunable-frequency qubit device. For instance, the absolute value of the anharmonicity of a tunable-frequency qubit device may be computed as |η|=|2ω₀₁−ω₀₂|, where ω₀₁ represents the transition frequency from the ground state |0 [symbol] to the first excited state |1 [symbol] of the tunable-frequency qubit device, and ω₀₂ represents the transition frequency from the ground state |0 [symbol] to the second excited state |2 [symbol] of the tunable-frequency qubit device.

In some implementations, device parameters of a dissipative coupler device include a dissipation factor. A value of the dissipation factor can be determined by operation of the dissipation calibration module 512 in FIG. 5 or in another manner. In some instances, different calibration operations are performed according to the types of the dissipative coupler device.

In some implementations, a control signal includes a flux bias signal that can be communicated to the tunable-frequency qubit device on a flux bias control line to tune the transition frequency. In some implementations, a control signal includes a flux modulation signal which can be communicated to the tunable-frequency qubit device on a flux bias control line to modulate the transition frequency. In certain instances, the control signal also includes a drive signal which can be communicated to the tunable-frequency qubit device on a distinct qubit drive control line to activate a single-qubit quantum logic gate. In certain instances, control signals, such as flux modulation signal and qubit drive signal, may be communicated to a qubit device on a common control line which is inductively and capacitively coupled to the qubit device. Control signals (e.g., a flux bias signal, a flux modulation signal, a qubit drive signal or another type of control signal) can be characterized by control parameters of the control signals including modulation parameters such as a DC flux bias Φ_{dc}, a flux modulation amplitude Φ_{ac}, a flux modulation frequency fₘ, a modulation phase θₘ, and drive parameters, such as a drive amplitude Ω_{d}, a drive frequency f_{d}, and a drive phase θ_{d}. In certain examples, the device parameters obtained from the device measurement process can be used to determine initial values of the control parameters of the control signals that can be applied to the respective quantum circuit devices, e.g., to activate a coupling between two qubit devices by tuning the coupler flux bias from a parking value to a gate-activating value, to deactivate a coupling between two qubit devices by tuning the coupler flux bias from a gate-activating value to a parking value, to bring two qubit devices into resonance for a precise time period, to activate a dissipative coupler device, and to perform other functions.

To perform the calibration, the control system of the example quantum computing system generates calibration signals, and the calibration signals are delivered to the quantum processing unit of the quantum computing system. The calibration signals can include, for example, microwave pulses applied to individual circuit devices (e.g., qubit devices), flux bias signals applied to individual coupler devices (e.g., tunable-frequency coupler devices), or other types of signals. The control system then obtains calibration measurements from the quantum processing unit, and the control system uses the calibration measurements to determine the control parameters. For instance, in the quantum computing system 500 shown in FIG. 5, the control system 502 can identify calibration signals that are configured to execute a pre-defined calibration routine, and the calibration signals can then be generated by the pulse sequence generator 510 and delivered to the quantum processing unit 504 in the quantum computing system 500. The pre-defined calibration routine can include, for example, the types of experiments, measurements, processes, optimization criteria or other features described in U.S. Pat. No. 10,282,675 entitled “Performing a Calibration Process in a Quantum Computing System;” other types of calibration routines may be used in some cases. During the calibration process, the control system 502 obtains calibration measurement results 505 from the quantum processing unit 504 and uses the calibration measurements in the calibration routine, for instance, to identify an improved or optimal value of one or more control parameters. The calibration measurements may include readout signals from resonator devices or other types of measurements obtained from the quantum processing unit 104A. The control parameters that are modified based on the calibration measurements can include, for example, the amplitude (power), frequency, duration, or phase of a microwave pulse; the amplitude (power), frequency, duration, or phase of a flux bias signal; or other types of control parameters for control signals.

In some implementations, calibration signals are generated (e.g., by operation of the control system 502 in FIG. 5) according to values of the control parameters (e.g., the initial values of the control parameters determined based on the device parameters or the improved values determined during the calibration process) and delivered to respective quantum circuit devices of the quantum processing unit (e.g., the qubit devices and the dissipative coupler devices where parametric dissipation operations are executed, or the qubit devices and non-dissipative coupler devices where a parametric quantum logic gate is executed). In order to perform a calibration measurement, calibration signals are communicated to respective quantum circuit devices to perform operations on the respective quantum circuit devices, e.g., tuning the effective coupling strength between two qubit devices, tuning the transition frequency of a tunable-frequency qubit devices, tuning the dissipation factor of dissipative coupler devices, and other operations.

In some cases, the calibration process (e.g., the dissipation calibration process and gate calibration process) may include a continuous-wave (CW) characterization procedure, which may include cavity spectroscopy measurements, qubit spectroscopy measurements, T1 and T2 measurements, and others. In some cases, the calibration process can include a pulsed characterization procedure, which may include cavity spectroscopy measurements, Rabi spectroscopy measurements, Ramsey spectroscopy measurements, power Rabi measurements, T1 and T2 measurements, and others. The CW or pulsed characterization procedures may perform measurements to detect the quality factor, resonance frequency, Lamb shift and other parameters of a device.

In some cases, the calibration process performed includes a gate tune-up procedure. For example, the gate tune-up procedure may include optimization of readout pulses or parameters, AC Stark coefficient measurements, pi-pulse amplitude tune-ups, Derivative Removal by Adiabatic Gate (DRAG) tune-ups, randomized benchmarking, other types of benchmarking, and others. The gate tune-up may include measurement of coupling strengths between qubit devices, characterization of tuning pulses for tunable-frequency qubit devices, and other types of measurements. In some cases, the calibration process includes a tune-up of multi-qubit quantum logic gates, single-qubit quantum logic gates, benchmarking procedures, or other types of processes.

In some cases, the calibration process may include a tune-up procedure for parametrically-activated two-qubit quantum logic gates. The parametrically-activated two-qubit quantum logic gate can be a quantum logic gate applied to a pair of qubits, where at least one of the qubits is defined on a tunable-frequency qubit device. The parametrically-activated two-qubit gate can be performed by modulating the resonance frequency of the tunable-frequency qubit device. The tune-up procedure can include, for example, characterizing both qubits, calibrating the flux drive line transfer function, determining a good candidate resonance for coupling, determining an amplitude for flux modulation, performing a multi-dimensional modulated flux pulse measurement, optimizing over pulse parameters, and other types of operations.

In some implementations, calibration of the parametric dissipation operations can be done through process tomography when sweeping control parameters, or in another manner. In some instances, a dissipation calibration process can be conducted on regular intervals to account for system drift. In addition to or separately, black-box optimization may be included that is calibration agnostic-instead relying on the overall variational algorithm's objective function or associated metrics to find optimized dissipation rate parameters.

In some implementations, the values of the control parameters of the control signals for applying a parametric dissipation operation or a parametric quantum logic gate are determined according to the values of the devices parameters and the estimated value of the dissipation rate parameter or the gate parameter. When a parametric dissipation operation is applied to one or more qubit devices, a computational state of at least one of the one or more qubit devices is set or reset to a target state with a probability corresponding to the estimated value of the dissipation rate parameter.

In some implementations, the values of the control parameters of the control signals for executing the parametric dissipation operations on a first set of quantum circuit devices defined by a first set of device parameters, and the parametric quantum logic gates on a second set of quantum circuit devices defined by a second set of device parameters are obtained from the calibration process and saved in a settings database of the control system (e.g., in the settings database 520, 530 in FIG. 5). When a specific quantum logic gate or a specific parametric dissipation operation is executed on a particular subset of quantum circuit devices in the quantum processing unit at during a time period, the pulse sequence generator 510 of the control system 502 generate the control signals according to the values of the control parameters stored in the settings database 520, 530.

At 208, a state of one or more of the qubit devices is measured. In some instances, the measured state of one or more of the qubit devices can be further used in later processes. For example, the measured state can be used in a classical optimization process 402 as part of the variational quantum algorithm 400 as shown in FIG. 4 or another process.

FIG. 3A is a block diagram showing aspects of an example quantum logic circuit 300. In some implementations, the example quantum logic circuit 300 represents part of a quantum approximation optimization algorithm or a quantum alternative operator Ansatz (QAOA) modified with engineered quantum dissipation. The example quantum logic circuit 300 includes unitary operations applied to qubits defined qubit devices of a quantum processing unit. In some instances, the example quantum logic circuit 300 includes unitary operations which may be generated by operation of a compiler in a server (e.g., the server 108 of the computing system 101 of FIG. 1) based on a quantum program (e.g., a user program) or may be received from a user device (e.g., the user device 110 of FIG. 1). In some implementations, the example quantum logic circuit 300 may be performed on a superconducting quantum processing unit (e.g., the example superconducting quantum processing unit 604 in FIG. 6) or other superconducting quantum processing unit or other quantum processor modalities. The unitary operations in a native quantum program are determined, for example by the server 108, according to the topology, connectivity, and other properties of the quantum processing unit. For example, when the superconducting quantum processing unit 604 is used, the qubit devices 212 and the associated coupler devices 214 in the example quantum processing unit 204 of FIG. 2 can be specified or selected by the server 108 on which the example quantum logic circuit 300 is performed.

The example quantum logic circuit 300 includes a first unitary operation 302. The first unitary operation 302 includes one or more single-qubit quantum logic gates (e.g., Hadamard gates) applied to qubit defined by the qubit devices (e.g., q₀, q₁, . . . qₙ) at a first time step t₁. When the qubit devices are communicably coupled to dissipative coupler devices, the first unitary operation 302 may further includes control operations to deactivate the dissipative coupler devices when the single-qubit quantum logic gates in the first unitary operation are performed in order to effectively isolate the qubit devices from neighboring qubit devices or dissipative coupler devices. Using the superconducting quantum processing unit 604 in FIG. 6 as an example, when the first unitary operation 302 is performed on a subset of quantum circuit devices 612A, 612B, 612C, 612D, 612E, 612F, 612G, 612H, 612I and their associated coupler devices 614, the coupler devices are deactivated. When the coupler device is a tunable-frequency transmon device for performing a multi-qubit quantum logic gate, the coupler device may be activated by the application of a coupler flux bias at a respective gate-activating value. When the coupler device is a dissipative coupler device (e.g., the first coupler devices 704A, 754A in FIGS. 7A-7B) for performing a parametric dissipation operation, the coupler device may be activated by the application of a coupler flux bias at a respective value according to a respective estimated value of the dissipation rate parameter. In some instances, a dissipative coupler device 614 can be enclosed in and coupled to a cavity, which can be further connected to a dissipation element on the transmission line (e.g., co-axial cable). In some implementations, the dissipation element is a capacitive dissipation element. In some implementations, the dissipation element represents a coupling between the qubit to the environment. In some implementations, a dissipative coupler device 614 may include other types of dissipation elements and may be operated in other fashions.

The example quantum logic circuit 300 includes second unitary operations 304 which include p alternating applications of a family of phase separation operators 312, a family of mixing operators 314, and a parameterized dissipation process 316. As shown in FIG. 3, the example quantum logic circuit 300 only shows one of the second unitary operations 304-1, which includes a first phase separation operator 312-1 at a second time step t₂, a first mixing operator 314-1 at a third time step t₃, and a first parameterized dissipation process 316-1 at a fourth time step t₄. In some instances, the phase-separation operator 312 depends on the objective function; and the mixing operator 314 depends on the domain and its structure. Each of the phase-separation operators 312 and each of the mixing operator 314 are defined by single real parameters γ and β, respectively. In some implementations, the parameterized dissipation process 316 is defined by a single parameter δ.

In some instances, when the example quantum logic circuit is associated with a native quantum program, the mixing operator 314 may include a sequence of partial mixing operators applied to respective pairs of qubits defined by respective coupled pairs of qubit devices. Similarly, the phase-separation operator 312 may include a sequence of partial phase-separation operators with all possible pairs of interactions applied to respective pairs of qubits defined by respective coupled pairs of qubit devices. For example, when a partial mixing operator or a partial phase-separation operator is applied to the qubit devices 612D, 612E, the dissipative coupler device 614F-2 can be deactivated; and the coupler device 614F-1 can be activated. At the same time, the coupler devices 614C, 614H, 614D-1, 614D-2, 614G-1, 614G-2, 614I-1, 614I-2 may be also deactivated to isolate the qubit devices 612D, 612E for performing the partial mixing operator or the partial phase-separation operator. In some instances, a pair of phase-separation operator 312 and mixing operator 314 may be decomposed into multiple pairs of a partial phase-separation operator and a partial mixing operator with all possible pairs of interactions. In some instances, a pair of a partial phase-separation operator and a partial mixing operator may be decomposed into a sequence of native quantum logic gates, e.g., CNOT gates with single qubit rotations, or XY and ZZ gates.

In some implementations, the example quantum logic circuit 300 further includes a third unitary operation 306 at a time step t₅. The third unitary operation 306 includes one or more single-qubit rotation operations applied to one or more qubits. The quantum logic circuit 300 further includes a fourth unitary operation 308 at a time step t₅. The fourth unitary operation 308 includes one or more measurement operators applied to the qubits. The example quantum logic circuit 300 may include additional or different unitary operations applied to additional qubits defined by additional qubit devices; include unitary operations performed by additional or different qubit devices; include additional or different unitary operations at additional time steps; and the unitary operations may be performed in the order shown or in another order.

In some implementations, the parameterized dissipation process 316 in the example quantum logic circuit 300 can be compiled into one or more single-qubit dissipation operations, two-qubit single-qubit dissipation operations, or other dissipation operations. In some instances, a user or a user program may specify or request one or more parameterized dissipation processes 316 with target values of parameters in a quantum logic circuit. The parametric dissipation operations may be determined according to available computing resources (e.g., the connectivity of the dissipative coupler devices that are included in the selected subset of quantum circuit devices for performing the quantum logic circuit 300); and the estimated values of the dissipation rate parameters of the dissipation operations are further determined according to the device parameters of the respective dissipative coupler devices and the qubit devices and the estimated values of the dissipation rate parameters that define the parametric dissipation operations.

FIG. 3B is a block diagram showing aspects of an example quantum logic circuit 320. In some implementations, the example quantum logic circuit 320 represents part of the quantum approximation optimization algorithm or a quantum alternative operator Ansatz (QAOA) modified with engineered quantum dissipation shown in FIG. 3A, part of the example quantum circuit ansatz 406 in FIG. 4, or another type of quantum program. The example quantum logic circuit 320 includes unitary operations applied to qubits defined qubit devices of a quantum processing unit. In some implementations, the quantum logic circuit 320 represents part of a native quantum program with native quantum logic gates and native parametric dissipative operations. In some instances, the example quantum logic circuit 320 includes unitary operations which may be generated by operation of a compiler in a server (e.g., the server 108 of the computing system 101 of FIG. 1) based on a quantum program (e.g., a user program) or may be received from a user device (e.g., the user device 110 of FIG. 1). In some implementations, the example quantum logic circuit 320 may be performed on a superconducting quantum processing unit (e.g., the example superconducting quantum processing unit 604 in FIG. 6) or other superconducting quantum processing unit or other quantum processor modalities.

As shown in FIG. 3B, the example quantum logic circuit 320 includes a set of transversal Hadamard gates applied to qubits defined by qubit devices (e.g., q₀, q₁, . . . qₙ) at a first time step t₁. A Hadamard gate 322 is configured to generate a target coherent superposition state on each of the qubit devices. The example quantum logic circuit 320 includes a first set of two-qubit CZ gates 324A at a second time step t₂, each of which is configured to generate entanglement across a pair of qubit devices. The example quantum logic circuit 320 includes a first set of parametric quantum logic gates at a third time step t₃, e.g., single rotation operations defined by θ, which may vary across different qubits. The example quantum logic circuit 320 includes a first set of parametric dissipation operations at a fourth time step t₄. The set of parametric dissipation operations may be applied to at least a subset of the qubits defined by at least a subset of qubit devices. In some implementations, the set of parametric dissipation operations includes single-qubit and two-qubit parametric dissipation operations defined by dissipation rate parameters (δ).

Some quantum logic gates and parametric dissipation operations can be repeated, or may be modified. As shown in FIG. 3B, the example quantum logic circuit 320 includes a second set of two-qubit CZ gates 326B at a fifth time step t₅, a second set of parametric quantum logic gates at a sixth time step t₆, and a second set of parametric dissipation operations at a seventh time step t₇. The second set of parametric dissipation operations may be applied to a different subset of the qubits defined by a different subset of qubit devices. The qubits of the qubit devices are then measured at an eighth time step t₈.

In some implementations, the parametric dissipation operations in the first and second sets of parametric dissipation operations 326A, 326B are separately operated from the quantum logic gates in 322, 324A, 326A, 324B, 326B. The parametric dissipation operations in the example quantum logic circuit 320 can be generated by operation of a compiler or specified by a user according to one or more objectives or criteria defined by the user or in a computer program.

In some instances, a parametric dissipative operation and a quantum logic gate, when applied to distinct quantum circuit devices, may be operated simultaneously during the same time step. Using the quantum processing unit 604 in FIG. 6 as an example, a two-qubit parametric dissipative operation can be applied to a pair of qubit devices 612D and 612E by deactivating the non-dissipative coupler device 614F-1, activating the dissipative coupler device 614F-2, deactivating coupler devices 614D-1, 614D-2 to isolate the qubit device 612E from the qubit device 612B, deactivating coupler devices 614G-1, 614G-2 to isolate the qubit device 612E from the qubit device 612F, deactivating coupler devices 614I-1, 614I-2 to isolate the qubit device 612E from the qubit device 612H. At the same time, a single-qubit quantum logic gate may be applied to the qubit device 612H by deactivating the coupler devices 614F, 614G to isolate the qubit device 612H from the qubit devices 612G, 612I. Similarly, during the same time step, a two-qubit quantum logic gate may be applied to the qubit devices 612H and 612I by deactivating the coupler devices 614F to isolate the qubit device 612H from 612G and deactivating the coupler device 614J to isolate the qubit device 612I from the qubit device 612F.

FIG. 4 is a schematic diagram showing aspects of an example variational quantum algorithm 400. The variational quantum algorithm 400 includes a hybrid quantum-classical loop to solve an optimization task. The variational quantum algorithm 400 can be performed in a computing system having shared quantum-classical memory for performing an iterative parameter search. For example, the variational quantum algorithm 400 may be performed in the quantum computing system 103 in FIG. 1 or in another type of hybrid computing system.

The example quantum algorithm 400 includes a quantum circuit ansatz 406 which includes unitary operations which includes one or more single-qubit quantum logic gates 412A, 412B, one or more two-qubit quantum logic gates 414A, 414B, or other quantum logic gate operations. In some implementations, a unitary operation also includes other control operations that can be performed on other quantum circuit devices. For example, controlled operations may include communicating coupler flux bias signals to coupler devices to activate or deactivate coupler devices. The quantum circuit ansatz 406 includes one or more parameterized dissipation process 416. The example quantum circuit ansatz 406 only shows two parameterized dissipation processes 416A, 416B.

When a two-qubit quantum logic gate 414A, 414B of the is applied to a pair of data qubit devices (modes A, B) capacitively coupled together via a coupler device (mode C), which can be modeled based on the steady-state analysis. Examples of the steady-state analysis are described in the publication entitled “Steady-state entanglement enhanced by a dissipative ancilla” by Joachim Fischbach and Matthias Freyberger (arXiv:1510.08247,[quant-ph], Oct. 28, 2015). Qubits defined by the two data qubit devices contribute to the total Hamiltonian with a static term (the first term on the right-hand side) and a coupling term (the second term on the right-hand side):

$$\frac{H}{ℏ} = {\sum }_{k ∈ \{ A , B , C \}} \frac{{ω}_{k} {Z}_{k}}{2} + {\sum }_{j , k ∈ \{ A , B , C \}} {J}_{j , k} {Z}_{j} {Z}_{k} \qquad ( 5 )$$

where ωₖ is the resonance frequency associated with each qubit device, J_{j,k} is the coupling strength between the qubit devices and the coupler device j and k; Zⱼ is the Pauli Z operator associated with the qubit defined by qubit device j; and Zₖ is the Pauli Z operator associated with qubit defined by qubit device k. In some implementations, the Hamiltonian is a leading order effect on currently available hardware, where the static capacitive interaction between detuned qubits gives rise to a dispersive ZZ interaction. The magnitude of this interaction can be tuned in-situ and dynamically (e.g., during an algorithm) by changing the detuning between qubits.

This Hamiltonian can be combined with coherent drives to produce unitary rotations capable of implementing universal gate-model computing, for instance as described in a publication entitled “NMR Techniques for Quantum Control and Computation” by Lieven M. K. Vandersypen and Isaac L. Chuang (arXiv:quant-ph/0404064, Jun. 10, 2004). In a noiseless setting, thus, this Hamiltonian can be used to produce perfect entanglement between modes A, B, C or subsets thereof. Importantly though, these computations are reversible until measurements are performed on the qubit devices because the system evolution is otherwise coherent.

In some implemented, a simple dissipation mechanism, single photon loss, to a zero-temperature bath under the Born-Markov approximation is incorporated to extend this model. The density matrix evolves as

$$\dot{ρ} ( t ) = - \frac{i}{ℏ} [ H ( t ) , ρ ( t ) ] + ℒ ( ρ ) \qquad ( 6 )$$

where [symbol] (ρ) is the dissipator, ρ is the density matrix, and [symbol] (ρ) can be further expressed as

$$ℒ ( ρ ) = {\sum }_{k ∈ \{ A , B , C \}} \frac{{γ}_{k}}{2} ( 2 {σ}_{k}^{-} {ρσ}_{k}^{+} - {σ}_{k}^{+} {σ}_{k}^{-} ρ - {ρσ}_{k}^{+} {σ}_{k}^{-} ) \qquad ( 7 )$$

where σₖ⁻ is the lowering operator associated with the k-qubit, e.g., σₖ⁻=|g [symbol] e|ₖ, σₖ⁺ is the raising operator associated with the k-qubit, e.g., σₖ⁺=|e [symbol] g|ₖ, γₖ is the dissipation rate parameter associated with qubit device k that defines the parameterized dissipation process. When the dissipation mechanism is added to the system, the dynamics of the system are no longer reversible. This model with the dissipation mechanism is capable of creating steady-state entanglement in the system. An optimized choice of dissipation rates and coupling strengths to result in boosted entanglement between qubits A, B in the attracted state can be determined. IN some instances, more complex dissipation mechanisms can have multiple attractor states or subspaces of the total Hilbert space that are stabilized under dissipation. Examples of the Hilbert space that are stabilized under dissipation are described in the publication entitled “Geometry and Response of Lindbladians” by Albert et al., arXiv: 1512.08079 [quant-ph], Nov. 16, 2016).

An application of a parameterized dissipation process can be used in an associated incremental process that drives input states to noisy outputs. A parameterized dissipation process can be programmed and controlled by tuning system parameters, such as the resonance frequencies ωₖ, the coupling between devices J_{j,k,} and the dissipation rate parameter γₖ; and can be further adjusted by an overall optimization loop.

During operation, a problem may be first encoded into a cost function which defines a hyper-surface such that the task of the optimizer is to navigate through the hyper-surface to find the global minima. The cost function contains a parameter set that can be optimized. In some implementations, when a cost function is defined, the parameter set is generated for an iteration of the variational quantum algorithm 400. A quantum circuit ansatz 406 can be defined according to the parameter set that can be optimized. The quantum processing unit is used to estimate the cost function and values of the parameters in the parameter set are optimized by executing the classical optimization process in the one or more classical processing units.

In some implementations, the quantum circuit ansatz 406 is parameterized according to the parameter set for the iteration, When the quantum circuit ansatz 406 is parameterized, the estimated value of the dissipation rate parameters is determined and the gate parameters for the quantum logic gates in the unitary operations are obtained. In some implementations, each of the unitary operations in the parameterized quantum circuit ansatz 406 includes unparameterized quantum logic gates.

When the parameterized quantum circuit ansatz 406 is executed on the quantum processing unit (e.g., the quantum processing unit 604 in FIG. 6), the parameterized quantum logic gates, the parametric dissipation operations determined based on the parameterized dissipation process, and the unparameterized quantum logic gates are applied to the qubits defined by the qubit devices. The output of the parameterized quantum circuit ansatz 406 is used to estimate the cost or its gradient, which is then fed into the classical optimizer to navigate the cost landscape and solve the optimization problem.

In some implementations, dissipation drive parameters include control parameters of the control signals applied to dissipative coupler devices associated with the qubit devices to tune the estimated value of the dissipation rate parameters. For example, when the coupler device is a dissipative coupler device having a fixed dissipation factor (e.g., the first coupler device 704A in FIG. 7A), the coupling between the qubit device and the dissipative coupler device can be tuned by the control signals. In some implementations, the dissipation drive parameter includes a duration of the control signal, a drive phase of the control signal, an amplitude of the control signal, and other parameters. In some implementations, values of the dissipation drive parameters of the control signals are determined according to the estimated values of the dissipation rate parameters and the values of device parameters of the quantum circuit devices that are involved in the parametric dissipation operations, which control the amount of quantum noise incorporated into the quantum algorithm 400. Such noise can be tailored to achieve entanglement or other resources during the execution of the quantum algorithm 400. In some instances, the dissipation drive parameters include other types of parameters according to the type of dissipative coupler devices and the respective control signals applied.

In some implementations, the quantum circuit ansatz 406 is defined which dictates what the parameter set is and how they can be trained to minimize the objective function. In some implementations, the quantum circuit ansatz 406 includes unitary operations; and each unitary operation includes or may be decomposed to a sequence of native quantum logic gates, for example, by operation of a compiler in a control system (e.g., the system compiler in FIG. 6). In some implementations, the sequence of native quantum logic gates in a compiled quantum program includes one or more native quantum logic gates defined by gate parameters. For instance, the sequence of native quantum logic gates may generally include any type of single-qubit parametric rotation, any type of two-qubit parametric interaction, a controlled (or a controlled-controlled) single-qubit parametric rotation, a controlled (or a controlled-controlled) two-qubit parametric interaction, or another type of parametric quantum logic gate. In some cases, the series of native quantum logic gates in the compiled quantum program also includes non-parametric gates. As shown in FIG. 5, the quantum circuit ansatz 406 further includes measurement operations 418.

In some implementations, regularization is included in the quantum circuit ansatz 406 after executing a subset of quantum logic gates to selectively remove parts of the multi-qubit Hilbert space. In some instances, the regularization may be obtained by a parameterized dissipation process which can be represented by one or more parameterized dissipation operations applied to one or more qubits defined by respective qubit devices. One or more parameterized dissipation processes 416 are included to achieve regularization on the quantum circuit ansatz 406. In particular, a first parameterized dissipation process 416A is included after a first set of single-qubit quantum logic gates 412A and two-qubit quantum logic gates 414A; and a second parameterized dissipation process 416B is included a second set of single-qubit quantum logic gates 412B and two-qubit quantum logic gates 414B. In some implementations, the first and second parameterized dissipation processes 416A, 416B are defined by respective parameters. The methods and techniques presented here enable robust solutions to both quantum noise and trainability.

During operation, the hybrid quantum-classical loop (e.g., iterative operations of 402, 404) of the example quantum algorithm 400 receives a training set wherein input states may be selected during the optimization, the objective function, and the quantum circuit ansatz 406. At each iteration of the loop, the quantum processing unit is used to estimate the cost. The cost information (e.g., readout from 404) is then fed to the classical computing system which navigates a cost landscape at different values of the input parameters (e.g., the gate parameters for parametric quantum logic gates and dissipation rate parameters for parametric dissipation operations) and solves the optimization problem. Once a termination condition is met, the computer program outputs an estimate of the solution to the problem. In some instances, the output of the example computer program includes quantum state, probability distribution, bitstring, gate sequence, quantum operator, or other types of output. In some instances, initial values of the input parameters (e.g., the gate parameters and dissipation rate parameters) are selected by the classical computing system, defined by the user, or in another manner.

FIG. 5 is a block diagram showing aspects of an example quantum computing system 500. The example quantum computing system 500 includes a control system 502 and a quantum processing unit 504. In some instances, the control system 502 may be implemented as the control system 105 in FIG. 1; and the quantum processing unit 504 may be implemented as the quantum processing unit 102 in FIG. 1. In some implementations, the example quantum computing system 500 can be used to perform the example variational quantum algorithm 400 in FIG. 4 or other types of quantum programs. The quantum computing system 500 may include additional or different features, and the components of a computing environment may operate as described with respect to FIG. 5 or in another manner.

As shown in FIG. 5, the control system 502 includes one or more classical processing units 508, a system compiler 506, a pulse sequence generator 510, and a memory device that stores ansatz description 503 and measurement results 505. The control system 502 further includes a dissipation calibration sub-system 540 for determining device parameters of quantum circuit devices by performing a dissipation calibration process and a gate calibration sub-system 550 for determining device parameters of quantum circuit devices by performing a gate calibration process.

As shown in FIG. 5, the dissipation calibration sub-system 540 includes a dissipation calibration module 512, numerical models 514, parameter sweeps 516, a tomography 518, and a settings database 520. In some implementations, the dissipation calibration module 512 is configured for re-calibration in the presence of drift based on previous data, for instance, measurements and analysis stored in the settings database 520. In some implementations, the dissipation calibration module 512 is automatically triggered to commence calibration, for instance, through a timer, calendar, or similar mechanism. In some implementations, the dissipation calibration module 512 is configured based on quantum circuit program data, for instance, using information that may include types of dissipation within a program, for instance, dissipation rates requested within a program or anticipated to occur in a future program instruction. Such information may be used in conjunction with other data, for instance, to determine which mechanisms are to be calibrated. In some implementations, the numerical models 514 are configured to produce emulations of physical processes to assist in determining device control parameters, such as driving frequencies, amplitudes, or phases of coupler drive signals that produce an intended dissipation effect. In some implementations, the parameter sweeps 516 are configured for determining the relationship between control mechanisms and the dissipation induced for the device. In some implementations, data analysis, which may include numerical models 514, may be used to fit, interpolate, or otherwise infer dissipation effects that have not been directly calibrated, and for example, such data may be used in subsequent protocols. In some implementations, the tomography 518 is configured for analyzing the quantum state or process that results from a quantum circuit program comprising a dissipation mechanism. Tomography may only contain partial information about the state or process under test, for instance limited to random projections in Hilbert space, sometimes referred to as classical shadows. In some implementations, the settings database 520 is configured to store and retrieve data that enables translation between a description of a dissipation mechanism that may include its type and dissipation rate and data relating to an associated physical structure.

The gate calibration sub-system 550 includes a gate calibration module 522, numerical models 524, parameter sweeps 526, a tomography 528, and a settings database 530. In some implementations, the gate calibration module 522 is configured for re-calibration in the presence of drift based on previous data, for instance, measurements and analysis stored in the settings database 530. In some implementations, the gate calibration module 522 is automatically triggered to commence calibration, for instance, through a timer, calendar, or similar mechanism. In some implementations, the gate calibration module 522 is configured based on quantum program data. In some implementations, the numerical models 524 are configured to produce emulations of physical processes to assist in determining device control parameters that produce an intended quantum logic gate. In some implementations, the parameter sweeps 526 are configured for determining the relationship between control mechanisms and quantum logic gates applied to qubit devices. In some implementations, data analysis, which may include numerical models 524, may be used to fit, interpolate, or otherwise infer gate parameters of quantum logic gates that have not been directly calibrated, and for example, such data may be used in subsequent protocols. In some implementations, the tomography 528 is configured for analyzing the quantum state or process that results from a quantum program. The tomography 528 may only contain partial information about the state or process under test, for instance limited to random projections in Hilbert space, sometimes referred to as classical shadows. In some implementations, the settings database 530 is configured to store and retrieve data that enables translation between a description of quantum circuit devices (e.g., types, device parameters and other information) to associated physical structures.

FIG. 6 is a schematic diagram showing aspects of an example quantum computing system 600. The example quantum computing system 600 shown in FIG. 6 may be deployed as one or more of the quantum computing systems (e.g., 103A, 103B) shown in FIG. 1, or the quantum computing system 600 may be deployed in another type of computing environment. As shown in FIG. 6, the example quantum computing system 600 includes a control system 602 and a quantum processing unit 604. The example quantum processing unit 604 may be implemented as the quantum processing unit 102 in FIG. 1. The example quantum computing system 600 may include additional or different features, and the components may be arranged in another manner.

In some instances, the quantum processing unit 604 is a superconducting quantum processing unit. In this case, the example quantum processing unit 604 includes a device array, which includes superconducting quantum circuit devices arranged in a two-dimensional layout. Twenty-five of the superconducting quantum circuit devices in the device array are shown in FIG. 6. In particular, the quantum processing unit 604 includes nine qubit devices 612 and sixteen coupler devices 214. The qubit devices 612 may be implemented as tunable-frequency transmon qubit devices, flux qubit devices, flatsonium qubit devices, fluxonium qubit devices, or other types of qubit devices. The qubit devices 612 may be implemented as fixed-frequency qubit devices or tunable-frequency qubit devices. The coupler devices 614 may be implemented as fixed-frequency coupler devices, tunable-frequency coupler devices, LC resonator devices, or other types of coupler devices. In some implementations, the quantum processing unit 604 shown in FIG. 6 is part (e.g., a two-dimensional grid on one layer) of a three-dimensional lattice, which includes multiple layers of two-dimensional grids shown in FIG. 6. A coupling between two qubit devices from two distinct layers may be achieved by a static capacitive coupling, a tunable-frequency coupling, or other types of coupling.

In the example shown in FIG. 6, the quantum circuit devices are arranged in a rectilinear (e.g., rectangular or square) array that extends in two spatial dimensions (in the plane of the page), and each qubit device 612 is communicably coupled with four other nearest-neighbor qubit devices 612 through a respective coupler device 614. For example, the qubit device 612B is coupled with qubit devices 612A and 612C through respective coupler devices 614A and 614B and qubit device 612A is also coupled with qubit device 612D through a coupler device 614C. In other words, two coupler devices 614A, 614C, are associated with the qubit device 612A. In some instances, the qubit device 612A may be coupled with other qubit devices in the same layer or in different layers. In some embodiments, a pair of qubit devices 612 may be coupled with each other through a pair of coupler devices 614. For example, a first pair of coupler devices 614D-1, 614D-2 reside between qubit devices 612B, 612E; a second pair of coupler devices 614F-1, 614F-2 reside between qubit devices 612d, 612E; a third pair of coupler devices 614G-1, 614G-2 reside between qubit devices 612F, 612E, and a fourth pair of coupler devices 614I-1, 614I-2 reside between qubit devices 612H, 612E. In other words, eight coupler devices 614D-1, 614D-2, 614F-1, 614F-2, 614I-1, 614I-2, 614G-1, and 614G-2 are associated with the qubit device 612E. In some implementations, the quantum circuit devices in the quantum processing unit 604 can be arranged in another type of ordered array. In some instances, the rectilinear array also extends in a third spatial dimension (in/out of the page), for example, to form a cubic array or another type of three-dimensional array. In this case, a qubit device may have a higher connectivity according to the number of the associated coupler devices. For example, the qubit device 612E may include additional coupler devices configured to provide coupling with other qubit devices residing at different layers of a three-dimensional lattice. In some implementations, a pair of coupler devices includes a dissipative coupler device and a non-dissipative coupler device.

In some aspects, parametrically activated quantum logic gates are supported in a two-dimensional or three-dimensional architecture (e.g., an architecture where quantum circuit devices are distributed over two or three spatial dimensions). For instance, the positions of the qubit devices within the example quantum processing unit 604 may define one or more two-dimensional spatial arrays in a plane, and readout resonators associated with the qubit devices can be positioned within another plane (e.g., on another processor substrate). In some cases, qubit devices 612 on one substrate 608 are electronically coupled to readout resonators on another substrate through conductive signal vias, interconnections, cap wafers, or other types of structures. Accordingly, frequency allocation schemes can be defined for two-dimensional and three-dimensional processor architectures.

In some implementations, the control system 602 interfaces with the quantum processing unit 604 through signal hardware that includes control lines 606. The control system 602 and control lines 606 may be implemented, for example, as described with respect to the controller 106 and the signal hardware 104 of the example control system 105 shown in FIG. 1, or in another manner.

In the example quantum processing unit 604 shown in FIG. 6, each of the qubit devices 612 can be encoded with a single bit of quantum information (a qubit). Each of the qubit devices has two eigenstates that are used as computational basis states, and each qubit device can transition between its computational basis states or exist in an arbitrary superposition of its computational basis states. In some examples, two lowest energy levels (e.g., the ground state |0 [symbol] and a first excited state |1 [symbol] of each qubit device are defined as a qubit and used as computational basis states for quantum computation. In some examples, higher energy levels (e.g., a second excited state |2 [symbol] or a third excited state |3 [symbol] are also defined by a multi-state quantum circuit device, and may be used for quantum computation in some instances.

In some implementations, the qubits of the respective qubit devices can be manipulated by control signals, or read by readout signals, generated by the control system 602. The qubit devices 612 can be controlled individually, for example, by communicating control signals to the respective qubit devices. In some cases, a coupler device 614 may be a tunable-frequency coupler device. In this case, the coupling between two qubit devices can be activated or deactivated by tuning the transition frequency of the associated tunable-frequency coupler device. Control signals can be communicated to the qubit devices and the associated tunable-frequency coupler device. In some implementations, associated tunable-frequency coupler devices include those that are in the same layer or between different layers in a three-dimensional lattice. In some cases, readout devices can detect the qubits of the qubit devices, for example, by interacting directly with the respective qubit devices.

In some examples, a tunable-frequency qubit device includes a superconducting circuit loop (e.g., a SQUID loop) that receives a magnetic flux which can tune the transition frequency of the tunable-frequency qubit device. In some instances, the transition frequency can be tuned within a range of frequencies (e.g., between a maximum transition frequency and a minimum transition frequency). The superconducting circuit loop may include two Josephson junctions, and the tunable-frequency qubit device may also include a shunt capacitor connected in parallel with each of the two Josephson junctions. In certain instances, the energy difference E between any two adjacent energy levels in a qubit device can be represented as a transition frequency w of the qubit device (e.g., according to ω=E/ [symbol] ). In some examples, a transition frequency is tunable, for example, by application of a magnetic flux. In this case, the transition frequency may be defined at least in part by Josephson energies of the two Josephson junctions, a capacitance of the shunt capacitor, and a magnetic flux threading the superconducting circuit loop. A qubit operating frequency of the tunable-frequency qubit device is a transition frequency at which the tunable-frequency qubit device operates.

In the example shown in FIG. 6, each qubit device 612 has one or more tunable transition frequencies. In some cases, the transition frequencies of the tunable-frequency qubit devices can be tuned by applying respective offset fields to the respective tunable-frequency qubit devices. Each of the offset fields can be, for example, a magnetic flux bias, a DC electrical voltage, or another type of field.

In some instances, information is encoded in the qubit devices 612 in the quantum processing unit 604, and the information can be processed by operation of the qubit devices 612. For instance, input information can be encoded in the computational states or computational subspaces defined by some or all of the qubit devices in the quantum processing unit 604. The information can be processed, for example, by applying a quantum program or other operations to the input information. The quantum program may be decomposed as a sequence of native quantum logic gates or instruction sets that are executed by quantum circuit devices in the quantum processing unit 604 over a series of clock cycles. In some cases, information is processed in another manner. Processing the information encoded in the qubit devices can produce output information that can be extracted from the qubit devices. The output information can be extracted, for example, by performing state tomography or individual readout operations. In some instances, the output information is extracted over multiple clock cycles or in parallel with the processing operations.

As shown in FIG. 6, the control system 602 is coupled to each of the superconducting quantum circuit devices (e.g., the qubit devices 612 and the coupler devices 614) in the quantum processing unit 604 through one or more control lines 606. For example, the control system 602 may communicate control signals to and receive readout signals from the quantum processing unit 604. The control signals communicated from the control system 602 to the qubit devices 612 can be configured to modulate, increase, decrease, or otherwise manipulate the qubit operating frequencies of the qubit devices 612. For example, a control signal may include a flux bias signal to tune the transition frequency of the tunable-frequency qubit device. For another example, a control signal may include a flux modulation signal that modulates a magnetic flux experienced by the tunable-frequency qubit device, and thus the transition frequency of the tunable-frequency qubit device. In some implementations, a control signal can be a direct current (DC) signal, an alternating current (AC) signal (e.g., superposed with a DC signal) communicated from the control system 602 to a qubit device 612. Other types of control signals may be used.

In some cases, the control lines 606 may include a flux bias device or another type of flux bias element that is inductively coupled to the superconducting circuit loop of a tunable-frequency qubit device to control the magnetic flux through a superconducting circuit loop in the tunable-frequency qubit device. The control signal may cause the flux-bias device to modulate the magnetic flux at a modulation frequency. In some instances, the modulation frequency of the magnetic flux may be the same as the flux modulation frequency ωₘ of the flux modulation signal, or the modulation frequency of the magnetic flux may have a different value.

In some implementations, a transition frequency (ω_{T}) of a tunable-frequency qubit device can be tuned by tuning a magnetic flux threading a superconducting circuit loop in the tunable-frequency qubit device. A magnetic flux can be modulated by communicating a flux modulation signal from the control system 602 to a flux bias element in a flux bias control line. Consequently, the transition frequency ω_{T} of the tunable-frequency qubit device can be modulated. In some instances, a flux modulation signal includes a flux modulation frequency (ωₘ) causing the transition frequency ω_{T} of a tunable-frequency qubit device to oscillate at a harmonic of the flux modulation frequency ωₘ. In some instances, the transition frequency ω_{T} under modulation is in a range of qubit operation frequencies which is defined by a tunability of a tunable-frequency qubit device. In some instances, a control signal may include a qubit drive signal which can drive the transition between two energy states (e.g., between the ground state and the first excited state) causing a population exchange between the ground state and the excited state.

In some implementations, control signals for a tunable-frequency qubit device including a flux modulation signal and a qubit drive signal can be communicated to the tunable-frequency qubit device on two separate control lines, e.g., a flux bias control line and a qubit drive control line. In some instances, the flux bias control line can be inductively coupled to the superconducting circuit loop to control the magnetic flux and thereby control the transition frequencies of the tunable-frequency qubit device. In certain examples, the qubit drive control line can be capacitively coupled to the tunable-frequency qubit device, e.g., through one or more qubit electrodes of the tunable-frequency qubit device. In this case, when a qubit drive signal and a flux modulation signal are communicated to the tunable-frequency qubit device through the respective control lines, a single-qubit quantum logic gate can be applied to a qubit defined by the tunable-frequency qubit device. In some instances, the flux modulation signal and the qubit drive signal may be communicated on a single control line that is both inductively and capacitively coupled to the tunable-frequency qubit device. In some instances, the transition frequency of the tunable-frequency qubit device or the tunable-frequency coupler device may be controlled in another manner.

In some implementations, the control system 602 (e.g., a gate calibration module), or another type of system associated with the quantum computing system 200, determines gate parameters for applying quantum logic gates in the quantum processing unit 604 by executing a gate calibration process. For example, the gate parameters may be determined by a gate calibration process defined in software, firmware or hardware, or a combination thereof. In some instances, initial values of the gate parameters for applying quantum logic gates of unitary operations in a quantum logic circuit may be selected by the control system 602 or obtained by the control system 602 (e.g., from a user device).

In some implementations, initial values of control parameters of control signals, e.g., the flux bias amplitude, the flux modulation frequency ωₘ, the flux modulation amplitude δω, the duration of the interaction produced by the flux modulation signal, or other control parameters of other control signals are determined based on the device parameters, e.g., transition frequencies, anharmonicities, data from a calibration or other test procedure, or a combination of these, the gate parameters, and other information.

In some cases, the control system 602 may execute a device measurement process, e.g., when the quantum processing unit 604 is first installed for use in the quantum computing system 600, and the device measurement process may be repeated at other times (e.g., as needed, periodically, according to a calibration schedule, etc.). For instance, a device measurement module may execute a measurement process that obtains device parameters of the quantum circuit devices in the quantum processing unit 604. The device parameters may be obtained by the device measurement process, for example, based on measurements of the quantum processing unit 604, based on a circuit specification of the quantum processing unit 604, based on analytical or numerical calculations, or otherwise. The device parameters may include, for example, qubit frequencies (e.g., a tunable range) and an anharmonicity for each tunable-frequency qubit device. In some instances, device parameters of the superconducting quantum circuit devices obtained from the device measurement process may be stored in a database, which can be used for determining initial values of control parameters of control signals to execute quantum logic gates on respective quantum circuit devices in the quantum processing unit 604.

In some implementations, the control system 602, or another type of system associated with the quantum computing system 600, further determines improved or optimal values of the control parameters of the control signals for executing quantum logic gates on respective quantum circuit devices in the quantum processing unit 604. For example, the improved or optimal values of the gate parameters may be determined by performing a hybrid variational quantum algorithm, or other types of quantum algorithm. In some cases, the calibration process can be performed by executing some or all of the operations in the example process 200 of FIG. 2 or in another manner.

In some instances, when a quantum program is defined and received by a computing system, a subset of superconducting quantum circuit devices of the quantum processing unit 604 can be selected for performing the quantum program, for example, by operation of the server 108 of the computing system 101 in FIG. 1. As shown in FIG. 6, quantum circuit devices are selected for performing a quantum program.

In some instances, the qubits of the respective qubit devices can be dissipated through the associated coupler devices in a controlled fashion by communicating control signals to the associated dissipative coupler devices. The control signals can be generated by the control system 202. In other words, the qubit devices have programmable dissipation rates, which can be tuned and modified by applying control signals to the coupler devices. Depending on the type of dissipative coupler devices, the control signals may be different. For example, when a dissipative coupler device is a tunable-frequency coupler device with a resistive dissipation element and the resistive dissipation element has a fixed resistance value, during a parametric dissipation operation (e.g., the parameterized dissipation process 316, 416 in FIGS. 3 and 4), a control signal may be a coupler flux bias signal, which tunes the dissipation rate of the qubit by tunning the effective coupling of the qubit device to the dissipative coupler device. For another example, when a dissipative coupler device is a tunable-frequency coupler deice with a resistive dissipation element and the resistive dissipation element has a tunable resistance value, the control signal can be a signal that controls the resistance value of the resistive dissipation element. For another example, when a second coupler drive signal is applied and tuned according to the estimated value of the dissipation rate parameter, the dissipation rate of the qubit defined by the qubit device can be tuned.

In some implementations, each qubit device 612 has an associated dissipative coupler device for single-qubit dissipation. In some implementations, a dissipative coupler device 614 is associated with multiple qubit devices 612 for multi-qubit dissipation. In this case, the control signal communicated to the coupler device is used to control the programmable dissipation rate of the qubit device through the coupler device. In some instances, a dissipation element is an ohmic dissipation element, a radiation dissipation element, or another types of dissipation elements.

In some instances, a high-level parameterized dissipation process on a quantum processing unit can be requested by the quantum program (e.g., a user program). In this case, one or more parametric dissipation operations for performing controlled dissipation on qubits are determined after a native quantum program is defined and compiled by operation of the control system according to the user program. When a parameterized dissipation operation is determined, estimated values of the dissipation rate parameters, qubits where the parametric dissipation operations are applied to, a number of iterations, and other parameters may be determined by operation of a compiler according to the received dissipation process, or can be directly specified by the user. For example, the one or more parametric dissipation operations are determined according to the topology of the quantum processing unit, device parameters of the quantum circuit devices of the quantum processing unit, quantum logic gates and other control operations in the native quantum program. In some instances, parameterized dissipation operations may be determined according to other factors or in another manner.

During the execution of quantum logic gates when no intended multi-qubit dissipation is needed for a pair of qubits, a different coupler device may be selected for the execution of the quantum logic gate and the dissipative coupler device can be turned off or deactivated. For example, a first coupler device 614F-1 is a non-dissipative coupler device, which has no dissipation or negligible dissipation with a dissipation factor less than a threshold value; and a second coupler device 614F-2 is a dissipative coupler device, which has a finite dissipation level (e.g., above a threshold value). In some instances, the parametric dissipation operations in the native quantum program are separated from the quantum logic gates in unitary operations. When a two-qubit quantum logic gate associated with a unitary operation of the quantum program is applied to qubits defined by qubit devices 612D, 612E, the first coupler device 614F-1 is activated, and the second coupler device 614F-2 is deactivated. When a two-qubit dissipation process is applied to the qubits defined by the qubit devices 612D, 612E, the second coupler device 614F-2 is activated, and the first coupler device 614F-1 is deactivated. In this case, the two-qubit parameterized dissipation process on the qubits is performed independently and separately from the two-qubit quantum logic gate applied to the same qubits. In some instances, the first and second coupler devices 614F-1, 614F-2 may be simultaneously activated, for example, when performing a dissipative quantum logic gate. In some instances, the first and second coupler devices 614F-1, 614F-2 may be simultaneously deactivated, for example, when a two-qubit quantum logic gate is applied to qubits defined by qubit devices 612D, 612G, or a two-qubit quantum logic gate is applied to qubits defined by qubit devices 612E, 612H. In some instances, the pair of dissipative and non-dissipative coupler devices may be operated in another manner.

The example quantum processing unit 604 shown in FIG. 6 resides on the top surface of a substrate 608. In certain instances, the substrate 608 may be an elemental semiconductor, for example silicon (Si), germanium (Ge), selenium (Se), tellurium (Te), or another elemental semiconductor. In some instances, the substrate 608 may also include a compound semiconductor such as aluminum oxide (sapphire), silicon carbide (SiC), gallium arsenic (GaAs), indium arsenide (InAs), indium phosphide (InP), silicon germanium (SiGe), silicon germanium carbide (SiGeC), gallium arsenic phosphide (GaAsP), gallium indium phosphide (GaInP), or another compound semiconductor. In some instances, the substrate 608 may also include a superlattice with elemental or compound semiconductor layers. In certain instances, the substrate 608 includes an epitaxial layer. In some examples, the substrate 608 may have an epitaxial layer overlying a bulk semiconductor or may include a semiconductor-on-insulator (SOI) structure.

In some instances, qubit electrodes and the ground plane of quantum circuit devices (e.g., qubit devices and coupler devices) include superconductive materials and can be formed by patterning one or more superconductive (e.g., superconducting metal) layers or other materials on the surface of the substrate 608. In some implementations, each of the one or more superconductive layers include a superconducting metal, such as aluminum (Al), niobium (Nb), tantalum (Ta), titanium (Ti), vanadium (V), tungsten (W), zirconium (Zr), or another superconducting metal. In some implementations, each of the one or more superconductive layers may include a superconducting metal alloy, such as molybdenum-rhenium (Mo/Re), niobium-tin (Nb/Sn), or another superconducting metal alloy. In some implementations, each of the superconductive layers may include a superconducting compound material, including superconducting metal nitrides and superconducting metal oxides, such as titanium-nitride (TiN), niobium-nitride (NbN), zirconium-nitride (ZrN), hafnium-nitride (HfN), vanadium-nitride (VN), tantalum-nitride (TaN), molybdenum-nitride (MoN), yttrium barium copper oxide (Y—Ba—Cu—O), or another superconducting compound material. In some instances, the qubit electrodes and the ground plane may include multilayer superconductor-insulator heterostructures.

In some implementations, the qubit electrodes and the ground plane of the quantum circuit devices are fabricated on the top surface of the substrate 608 and patterned using a microfabrication process or in another manner. For example, the qubit electrodes and the ground plane may be formed by performing at least some of the following fabrication steps: using chemical vapor deposition (CVD), physical vapor deposition (PVD), atomic layer deposition (ALD), spin-on coating, and/or other suitable techniques to deposit respective superconducting layers on the substrate 608; and performing one or more patterning processes (e.g., a lithography process, a dry/wet etching process, a soft/hard baking process, a cleaning process, etc.) to form openings in the respective superconducting layers.

FIG. 7A is a circuit diagram showing aspects of an example equivalent circuit 700 of an example superconducting quantum processing unit. The equivalent circuit 700 represented in FIG. 7A includes a first tunable-frequency qubit device 702A, a second tunable-frequency qubit device 702B, a first coupler device 704A, and a second coupler device 704B. The example equivalent circuit 700 further includes control lines connected to the first and second tunable-frequency qubit devices 702A, 702B and the first and second coupler devices 704A, 704B. For example, the equivalent circuit 700 includes a first qubit drive line 718A capacitively coupled to the first tunable-frequency qubit device 702A and a first flux bias control line 718B inductively coupled to the first tunable-frequency qubit device 702A; and a second qubit drive line 728A capacitively coupled to the second tunable-frequency qubit device 702B and a second flux bias control line 728B inductively coupled to the second tunable-frequency qubit device 702B. As shown in FIG. 7A, the equivalent circuit 700 further includes a first coupler drive line 738A capacitively coupled to the first coupler device 704A and a first coupler flux bias control line 738B inductively coupled to the first coupler device 704A; a second coupler drive line 748A capacitively coupled to the second coupler device 704B, and a second coupler flux bias control line 748B inductively coupled to the second coupler device 704B.

In some examples, the tunable-frequency qubit devices 702A, 702B and the coupler devices 704A, 704B may be implemented by other types of systems, and the features and components represented in FIG. 7A can be extended in a larger two-dimensional or three-dimensional array of devices. For instance, the equivalent circuit 700 in FIG. 7A can represent the qubit devices 612E and one of its neighboring qubit devices 612B, 612D, 612F, or 612H in the superconducting quantum processing unit 604 in FIG. 6, or the equivalent circuit 700 in FIG. 7A can represent devices in another type of system or environment. In some implementations, the first coupler device 704A is a dissipative coupler device, and is configured to, when being activated, perform programmable dissipation in the coupled qubit devices 702A, 702B; and the second coupler device 704B is a non-dissipative coupler device, and is configured to, when being activated, couple the two tunable-frequency qubit devices 702A, 702B for executing a two-qubit quantum logic gate. The quantum computing system may include additional or different features, and the components may be arranged as shown or in another manner. For example, the first or second tunable-frequency qubit devices 702A, 702B may be coupled to other qubit devices through other coupler devices.

In the example shown in FIG. 7A, the first tunable-frequency qubit device 702A is implemented as a tunable-frequency transmon qubit device. As shown, the first tunable-frequency qubit device 702A includes two Josephson junctions, e.g., a first Josephson junction 712A and a second Josephson junction 712B. The first and second Josephson junctions 712A, 712B having Josephson energies are connected in parallel with each other to form a superconducting circuit loop 719, which resides adjacent to the first flux bias control line 718B. The first tunable-frequency qubit device 702A also includes a capacitor 714 with a shunt capacitance, which is connected in parallel with the two Josephson junctions 712A, 712B. In some instances, the first flux bias control line 718B is coupled to a first flux bias element 717 (e.g., a conductor, an inductor, or another type of circuit component configured to carry a current I), which generates a magnetic flux Φ(t) through the superconducting circuit loop 719 in the first tunable-frequency qubit device 702A. The magnetic flux can be modulated by communicating a flux modulation signal on the first flux bias control line 718B which causes a modulation to the transition frequency of the first tunable-frequency qubit device 702A.

In the example shown in FIG. 7A, the second tunable-frequency qubit device 702B is implemented as a tunable-frequency transmon qubit device. As shown, the second tunable-frequency qubit device 702B includes two Josephson junctions, e.g., a third Josephson junction 722A and a fourth Josephson junction 722B. The third and fourth Josephson junctions 722A, 722B having Josephson energies are connected in parallel with each other to form a superconducting circuit loop 729, which resides adjacent to the second flux bias control line 728B. The second tunable-frequency qubit device 702B also includes a capacitor 724 with a shunt capacitance, which is connected in parallel with the two Josephson junctions 722A, 722B. In some instances, the second flux bias control line 728B is coupled to a second flux bias element 727 (e.g., a conductor, an inductor, or another type of circuit component configured to carry a current I), which generates a magnetic flux Φ(t) through the superconducting circuit loop 729 in the second tunable-frequency qubit device 702B. The magnetic flux can be modulated by communicating a flux modulation signal on the second flux bias control line 728B which causes a modulation to the transition frequency of the second tunable-frequency qubit device 702B.

In the example shown in FIG. 7A, the first coupler device 704A is implemented as a tunable-frequency transmon qubit device. As shown, the first coupler device 704A includes two Josephson junctions, e.g., a fifth Josephson junction 732A and a sixth Josephson junction 732B. The fifth and sixth Josephson junctions 732A, 732B having Josephson energies are connected in parallel with each other to form a superconducting circuit loop 739, which resides adjacent to the first coupler flux bias control line 738B. The first coupler device 704A also includes a capacitor 734 with a shunt capacitance, which is connected in parallel with the two Josephson junctions 732A, 732B. In some instances, the first coupler flux bias control line 738B is coupled to a third flux bias element 737 (e.g., a conductor, an inductor, or another type of circuit component configured to carry a current I), which generates a magnetic flux Φ(t) through the superconducting circuit loop 739 in the first coupler device 704A. The magnetic flux can be modulated by communicating a flux modulation signal on the first coupler flux bias control line 738B which causes a modulation to the transition frequency of the first coupler device 704A.

In the example shown in FIG. 7A, the second coupler device 704B is implemented as a tunable-frequency transmon qubit device. As shown, the second coupler device 704B includes two Josephson junctions, e.g., a seventh Josephson junction 742A and an eighth Josephson junction 742B. The seventh and eighth Josephson junctions 742A, 742B having Josephson energies are connected in parallel with each other to form a superconducting circuit loop 749, which resides adjacent to the second coupler flux bias control line 748B. The second coupler device 704B also includes a capacitor 744 with a shunt capacitance, which is connected in parallel with the two Josephson junctions 742A, 742B. In some instances, the second coupler flux bias control line 748B is coupled to a fourth flux bias element 747 (e.g., a conductor, an inductor, or another type of circuit component configured to carry a current I), which generates a magnetic flux Φ(t) through the superconducting circuit loop 749 in the second coupler device 704B. The magnetic flux can be modulated by communicating a flux modulation signal on the second coupler flux bias control line 748B which causes a modulation to the transition frequency of the second coupler device 704B.

In some instances, the first and second tunable-frequency qubit device 702A, 702B can be coupled together through the first coupler device 704A, when the first coupler device 704A is activated and the second coupler device is deactivated. In this case, a programmable dissipation operation can be performed on the first and second tunable-frequency qubit devices 702A. 702B. In some instances, the first and second tunable-frequency qubit device 702A, 702B can be coupled together through the second coupler device 704B, when the first coupler device 704A is deactivated and the second coupler device 704B is activated. In this case, a two-qubit quantum logic gate can be performed on the first and second tunable-frequency qubit devices 702A, 702B. The first coupler device 704A is capacitively coupled to each of the first and second tunable-frequency qubit devices 702A, 702B via respective residual capacitors 742A, 742B; and the second coupler device 704A is capacitively coupled to each of the first and second tunable-frequency qubit devices 702A, 702B via respective residual capacitors 752A, 752B.

In some implementations, each of the first and second tunable-frequency qubit devices 702A, 702B has a transition frequency ω_{T}_{₀₁}(t) that can be tuned over time. In this example, the tunability of the transition frequencies of the first and second tunable-frequency qubit devices 702A, 702B can be used to perform two-qubit quantum logic gates. For instance, by modulating the transition frequencies ω_{T}_{₀₁}(t) of the tunable-frequency qubit device 702A, 702B at predetermined values of the flux modulation frequency and flux modulation amplitude, a two-qubit quantum logic gate can be activated between the two qubit devices 702A, 702B.

In some implementations, control operations can be performed by providing control signals to the tunable-frequency qubit devices 702A, 702B and the coupler devices 704A, 704B via control lines. The control lines can receive the control signals, for example, from an external control system. In some implementations, each of the control lines can be connected to a conductor, an inductor, or another type of circuit component configured to carry a respective current I, which generates a respective magnetic flux Φ(t) through the superconducting circuit loops 719, 729, 739, 749. For instance, the control line may include an inductor (e.g., a partial loop, a single loop, or multiple loops of a conductor) that has a mutual inductance with the superconducting circuit loop 719, 729, 739, 749. In the example shown, the transition frequency of the first tunable-frequency qubit device 702A is tuned by tuning a magnetic flux in the superconducting circuit loop 719; the transition frequency of the second tunable-frequency qubit device 702B is tuned by tuning a magnetic flux in the superconducting circuit loop 729; the transition frequency of the first coupler device 704A is tuned by tuning a magnetic flux in the superconducting circuit loop 739; and the transition frequency of the second coupler device 704B is tuned by tuning a magnetic flux in the superconducting circuit loop 749. In some instances, the transition frequencies may be controlled in another manner, for instance, by another type of control signal. In some implementations, the control lines may be connected to an inductance loop or another type of flux bias element that is coupled (e.g., conductively, capacitively, or inductively) to a control port to receive control signals. In certain instances, the control signals on the control lines may cause the flux bias element 717, 727, 737, 747 to generate and modulate the magnetic flux in the superconducting circuit loop 719, 729, 739, 749. In some implementations, the control signals on the control line are flux bias signals or flux modulation signals; and are implemented as the control signals 206 as shown in FIG. 2.

In some instances, the first coupler device 704A is a dissipative coupler device including one or more dissipation elements. For example, a dissipation element can be an ohmic dissipation element which can be caused by the conductive and resistive losses in a superconducting circuit. In some instances, a dissipation element includes dielectric loss or two-level system loss in a capacitor, quasiparticle loss, AC loss and ground plane loss. In particular, as shown in FIG. 7A, the first coupler device 704A includes a resistive dissipation element 740. In some instances, the resistive dissipation element 737 has a fixed resistance value or a variable resistance.

In some implementations, when the second coupler device 704B is deactivated and the two tunable-frequency qubit devices 702A, 702B are only coupled through the first coupler device 704A with a dissipation element of a fixed resistance value, dissipation of the two tunable-frequency qubit devices 702A, 702B is controlled by tunning the effective coupling between the two tunable-frequency qubit devices 702A, 702B. In some instances, the first coupler device 704A can be activated; and the effective coupling between the first coupler device 704A and each of the tunable-frequency qubit devices 702a, 702B can be tuned by tuning a magnetic flux applied to the first coupler device 704A. For example, a separate control signal (e.g., a DC or an AC current) can be applied to the first coupler flux bias control line 738B to tune the magnetic flux threading to the superconducting circuit loop 739 of the first coupler device 704A to adjust the transition frequency of the first coupler device 704A. When the magnetic flux on the first coupler device 704A is at a parking value, the coupling between the two tunable-frequency qubit devices 702A, 702B or the first coupler device 704A can be turned off or deactivated. When the magnetic flux on the first coupler device 704A is at a dissipation-activating value, the coupling between the two tunable-frequency qubit device 702A, 702B can be activated for performing a parameterized dissipation operation at a maximum dissipation rate. In some instances, when the magnetic flux on the first coupler device 704A is between the parking value and the dissipation-activating value, the dissipation of the first and second tunable-frequency qubit devices 702A, 702B can be set an intermediate value. Thus, the dissipation of the tunable-frequency qubit devices 702A, 702B is programmable and can be tuned by the first coupler flux bias control signal. In some instances, values of the dissipation rate parameters can be tuned by tunning the effective coupling of each of the qubit devices 702A, 702B to the coupler device 704. In some instances, operation for activating and deactivating the tunable-frequency coupler device 906 can be implemented with respect to operations by the dissipation calibration module of the example system 500 shown in FIG. 5 or in another manner.

In some implementations, when the two tunable-frequency qubit devices 702A, 702B are coupled through the first coupler device 704A with a dissipation element of a variable resistance value, the dissipation of the two tunable-frequency qubit devices 702A, 702B is controlled by tunning the resistance value of the dissipation element in the first coupler device 704A. In this case, the coupling between the two qubit devices may be set at its maximum value with the magnetic flux on the coupler device 704 at its dissipation-activation value; and values of the dissipation rate parameters can be tuned may be tuned by tunning the resistance value of the dissipation element.

In some implementations, when the first coupler device 704A is deactivated and the two tunable-frequency qubit devices 702A, 702B are only coupled through the second coupler device 704A the effective coupling between the two tunable-frequency qubit devices 702A, 702B can be controlled by tuning a magnetic flux applied to the second coupler device 704B. For example, a separate control signal (e.g., a DC or an AC current) can be applied to the second coupler flux bias control line 748B to tune the magnetic flux threading to the superconducting circuit loop 749 of the second coupler device 704B to adjust the transition frequency of the second coupler device 704B. When the magnetic flux on the second coupler device 704B is at a parking value, the coupling between the two tunable-frequency qubit devices 702A, 702B or the second coupler device 704B can be turned off or deactivated. When the magnetic flux on the second coupler device 704B is at a gate-activating value, the coupling between the two tunable-frequency qubit device 702A, 702B or the second coupler device 704B can be turned on or activated for performing a parameterized two-qubit quantum logic gate. In some instances, operation for determining the activating and deactivating conditions of the second coupler device 704B can be implemented with respect to operations by the gate calibration module 522 of the example system 500 shown in FIG. 5 or in another manner.

FIG. 7B is a circuit diagram showing example equivalent circuit 750 of an example superconducting quantum processing unit. The equivalent circuit 750 represented in FIG. 7B includes a first tunable-frequency qubit device 752A, a second tunable-frequency qubit device 752B, a first coupler device 754A, and a second coupler device 754B. The example equivalent circuit 750 further includes control lines connected to the tunable-frequency qubit devices 752A, 752B and the coupler devices 754A, 754B. In some instances, the first and second tunable-frequency qubit devices 752A, 752B may be implemented as the first and second tunable-frequency qubit devices 702A, 702B in FIG. 7A or in another manner.

As shown in FIG. 7B, the first coupler device 754A includes a resonator device (e.g., an inductor-capacitor resonator device). The first coupler device 754A, in this case, has a fixed resonance frequency. As shown, the first coupler device 754A includes a capacitor 734 with a shunt capacitance and a inductor 764 with a inductance. The coupler device 754 further includes a resistive dissipation element 762. In some instances, the second coupler device 754B can be implemented as the second coupler device 704B in FIG. 7A or in another manner.

In certain instances, the first coupler device 754A may be coupled to multiple qubit devices. The dissipation rate of the first and second tunable-frequency qubit devices 752A, 752B is set through static (e.g., capacitive) coupling to the first coupler device 754A. The first coupler device 754A is a resonator device with a quality factor equal to or less than 1000. In some implementations, the first coupler device 754A has a linear dissipation via the Purcell effect. In this case, the dissipation on the first coupler device 754A is of a driven, engineered form, for instance via side-band processes, which can convert excitations from the tunable-frequency qubit devices 752A, 752B to the first coupler device 754A, which is a low-Q (e.g., Q˜1000) linear resonator. Side-band processes can be achieved, for example, with respective RF drive signals communicated to the respective quantum circuit devices via respective capacitive coupling through the respective drive lines 718A, 738A, 728A, where the parameters of the respective RF drive signals are selected to conserve energy during the frequency conversion between modes. As an example, single-qubit dissipation can be increased by driving at a frequency that approximates the difference frequency of the first coupler device 754A and the qubit mode. As an example, multi-qubit dissipation can be increased by driving at a frequency that approximates the total difference frequency of the first coupler device 754A subtracted by the combination of qubit mode frequencies. As an example, first and second tunable-frequency qubit devices 752A, 752B may be brought into resonance with the first coupler device 754A via DC or parametric driving of the flux bias. In this case, the dissipation of qubits defined by the qubit devices is via radiation onto a transmission line or other lossy elements. In some instances, the first coupler device 754A is lossier than the qubit devices 752A, 752B, and the second coupler device 754B. The relative loss rates of elements on a processor may change during the course of an algorithm, as well as the absolute rate.

In some implementations, the qubit-resonator dispersive coupling strength between the first tunable-frequency qubit devices 752A and the first coupler device 754A is substantially equal to the qubit-resonator dispersive coupling strength between the second tunable-frequency qubit devices 752B and the first coupler device 754A. In some implementations, the difference between the two qubit-resonator dispersive coupling strengths is equal to or less than a threshold value. In this case, the qubit devices 752A, 752B may have the same or comparable dissipation rates. Future optimizations could include increasing the linear dissipation of the first coupler device 754A, for instance by additional capacitance to a damped LC oscillator (e.g., readout mode) to the point of that first coupler device 754A itself being strongly Purcell limited (e.g., energy dissipation through the Purcell radiation is above 50% or another value). That is, its lifetime is determined more by the intentional admittance presented by the chip design than by other losses, such as intrinsic material losses.

In some instances, increasing E_{J}/E_{C} ratios of the qubit devices (e.g., the tunable-frequency qubit devices 704A, 704B, 754A, 754B, or other quantum circuit devices) across the processor allows accessing additional Hilbert space, which can be helpful for engineered quantum dissipation (EQD) schemes. Implementing variational engineered quantum dissipation (VEQD) on such a multi-level processor can be improved if a single RF digital analog converter with multiple numerically controlled oscillators is the source of stabilization drives, since each transition may require unique frequency addressing. Moreover, a common timing reference across the system is included in the control system to phase lock the various EQD drive signals (e.g., the coupler drive signal on the coupler drive line 738A and the coupler flux bias signal on the coupler flux bias line 738B in FIG. 7A) and with the RF synthesis described above, the relative phases can be adjusted digitally, which enables the shared memory model to extend to EQD schemes. That is, control parameters of the EQD drive signals such as their relative or absolute phases and/or amplitudes and/or duration can be adjusted by updating the control parameters in the embedded controller (e.g., in the dissipation calibration module 512) without requiring a recompilation of the program.

In certain instances, multi-qubit transitions that involve converting excitations from the qubit devices into the dissipative coupler device (e.g., the 702A, 702B into the first coupler device 704A in FIG. 7A, or the tunable-frequency qubit devices 752A, 752B into the first coupler device 754A in FIG. 7B) can be achieved, conditional on the state of more than one of the qubit devices. For instance, anti-correlated ZZ states of two qubit devices, e.g., ρ=α|01 [symbol] 01|+b|10 [symbol] 10| can be stabilized by driving the parametric transition |110 [symbol] ↔|002 [symbol] (where the third index is the dissipative coupler device), while pumping the qubit devices with qubit drive signals. The state |002 [symbol] quickly decays to |000 [symbol] , thus depopulating the state |11 [symbol] of the qubit devices. Meanwhile, the qubit drive signals (e.g., on the qubit drive lines 718A, 728A) applied to the qubit devices pump population out of the |00 [symbol] state of the qubit devices. In some implementations, this correlation influences the output of the variational quantum algorithm (e.g., the variational quantum algorithm 400 in FIG. 4) or other quantum programs.

As shown in FIG. 7B, the first coupler device 754A is a resonator device whose dissipation is set through static (e.g., capacitive coupling) to a transmission line. In some instances, the dissipation can be set to a transmission line further to an attenuator device. In some implementations, the methods and systems presented here can be used to generate and stabilize correlated states of qubit devices through dispersive interactions between each of the qubit device 752A, 752B and the first coupler device 754A. The difference between the strength values of the dispersive interactions is zero, about zero, or less than a threshold value; and each of the strength values of the dispersive interactions is equal to or less than the dissipation rate of the first coupler device 754A.

In some implementations, the systems and techniques described herein can provide technical advantages and improvements. For example, EQD systems have been considered for analog quantum simulators (in particular for AMO systems), by mimicking the dissipation of a model system. Topological systems are a natural choice for target simulation domains since the underlying physics (e.g., phase transitions) are similar to the dynamics in EQD. Importantly, these simulations by and large consist of state preparation and investigation. Here, we allow for exploring a broader parameter setting landscape, and allow for gates in the ansatz or state preparation. For instance, during a dissipation calibration process by operation of the dissipation calibration module 512 in FIG. 5, one may pump the system with EQD drive signals for much less than the stabilization rate in each increment, and learn optimal amounts of dissipation.

In a general aspect, a quantum processing unit includes dissipative coupler devices which are operated during an execution of a quantum program.

In a first example, a method includes executing a computer program in a computer system. Executing the computer program includes applying a quantum logic gate associated with a unitary operation to qubits defined by qubit devices on a quantum processing unit; obtaining an estimated value of a dissipation rate parameter; applying a parametric dissipation operation to one or more of the qubit devices; and measuring a state of one or more of the qubit devices. The parametric dissipation operation has a programmable dissipation rate that is controlled by the estimated value of the dissipation rate parameter; and the parametric dissipation operation is applied separately from the quantum logic gate.

Implementations of the first example may include one or more of the following features. The method includes obtaining a target state. Applying the parametric dissipation operation sets or resets a computational state of at least one of the one or more qubit devices to the target state with a probability corresponding to the estimated value of the dissipation rate parameter. Obtaining the estimated value of the dissipation rate parameter includes obtaining the estimated value of the dissipation rate parameter from the computer program. The method includes obtaining information about a stochastic effect and a target value of the dissipation rate parameter. The computer system includes a compiler. Obtaining the estimated value of the dissipation rate parameter includes computing the estimated value of the dissipation rate parameter according to the target value of the dissipation rate parameter by operation of the compiler. The parametric dissipation operation is configured to approximate the stochastic effect.

Implementations of the first example may include one or more of the following features. The computer program is a hybrid classical-quantum program comprising classical computing operations and quantum computing operations. Executing the computer program in the computer system includes executing the classical computing operations on at least one classical processing unit. Obtaining the estimated value of the dissipation rate parameter includes computing the estimated value of the dissipation rate parameter based on an output of the classical computing operations.

Implementations of the first example may include one or more of the following features. Executing the computer program in the computer system includes executing a variational quantum algorithm. The variational quantum algorithm includes a quantum circuit ansatz, and a classical optimization process. Executing the variational quantum algorithm includes iteratively: generating a parameter set for an iteration of the variational quantum algorithm; parameterizing the quantum circuit ansatz according to the parameter set for the iteration; and executing the parameterized quantum circuit ansatz on the quantum processing unit. The parameter set is generated based on one or more classical processing units executing the classical optimization process. Parameterizing the quantum circuit ansatz includes determining the estimated value of the dissipation rate parameter. Executing the parameterized quantum circuit ansatz includes applying the parametric dissipation operation. Parameterizing the quantum circuit ansatz includes obtaining parameters for the quantum logic gate; and executing the quantum circuit ansatz includes applying the parameterized quantum logic gate. Executing the computer program includes preparing the qubits in an initial state defined by the computer program. Preparing the qubits in the initial state includes applying the parametric dissipation operation.

Implementations of the first example may include one or more of the following features. The quantum processing unit includes coupler devices coupled to the qubit devices, each coupler device comprises a dissipation element. Applying the parametric dissipation operation includes generating dissipation drive signals for the coupler devices based on the estimated value of the dissipation rate parameter; and communicating the dissipation drive signals to the coupler devices. The coupler devices are first coupler devices. The quantum processing unit includes second coupler devices coupled to the qubit devices. The dissipation drive signals are first dissipation drive signals. Each second coupler device includes no dissipation element. Applying the quantum logic gate includes generating coupler flux control signals for the second coupler devices; communicating the coupler flux control signal to the second coupler devices; generating second dissipation drive signals for the first coupler devices to deactivate the first coupler devices; and communicating the second dissipation drive signals to the first coupler devices.

Implementations of the first example may include one or more of the following features. The dissipation elements include ohmic dissipation elements. Each ohmic dissipation element includes a transmission line communicably coupled between the coupler device and an attenuator device. The coupler devices include resonator devices. Each of the coupler devices includes a tunable-frequency coupler device. The tunable-frequency coupler device includes a superconducting circuit loop with two Josephson junctions connected in parallel. The dissipation element is an ohmic dissipation element in parallel with the two Josephson junctions. The quantum processing unit is a superconducting quantum processing unit; and the coupler devices are capacitively coupled to the qubit devices. The qubit devices include a first qubit device and a second qubit device communicably coupled to the first qubit device through a common coupler device. The parametric dissipation operation includes a first control operation applied to the common coupler device, and the first control operation is configured to control application of the parametric dissipation operation to the first and second qubit devices. A programmable dissipation rate of the parametric dissipation operation applied to the first and second qubit devices is greater than or equal to an indirect qubit-qubit coupling rate between the first and second qubit devices.

In a second example, a computer system includes a quantum processing unit including qubit devices and a control system communicably coupled to the quantum processing unit and is configured to perform one or more operations in the first example.

Some of the operations described in this specification can be implemented as operations performed by a data processing apparatus on data stored on one or more computer-readable storage devices or received from other sources. For example, calibration programs described herein may be implemented by computer programs on the data processing apparatus.

The term “data-processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them.

A computer program (also known as a program, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program, or in multiple coordinated files (e.g., files that store one or more modules, sub programs, or portions of code). A computer program can be deployed to be executed on one computer or on multiple computers that are located at one site or distributed across multiple sites and interconnected by a communication network.

Some of the processes and logic flows described in this specification can be performed by one or more programmable processors executing one or more computer programs to perform actions by operating on input data and generating output. The processes and logic flows can also be performed by, and apparatus can also be implemented as, special purpose logic circuitry, e.g., an FPGA (field programmable gate array) or an ASIC (application specific integrated circuit).

While this specification contains many details, these should not be understood as limitations on the scope of what may be claimed, but rather as descriptions of features specific to particular examples. Certain features that are described in this specification or shown in the drawings in the context of separate implementations can also be combined. Conversely, various features that are described or shown in the context of a single implementation can also be implemented in multiple implementations separately or in any suitable sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single product or packaged into multiple products.

A number of embodiments have been described. Nevertheless, it will be understood that various modifications can be made.

1. A method comprising:
executing a computer program in a computer system, wherein executing the computer program comprises:
applying a quantum logic gate associated with a unitary operation to qubits defined by qubit devices on a quantum processing unit;
obtaining an estimated value of a dissipation rate parameter;
applying a parametric dissipation operation to one or more of the qubit devices, wherein the parametric dissipation operation has a programmable dissipation rate that is controlled by the estimated value of the dissipation rate parameter, the parametric dissipation operation being applied separately from the quantum logic gate; and
measuring a state of one or more of the qubit devices.

2. The method of claim 1, comprising:
obtaining information of a target state of at least one of the one or more qubit devices,
wherein applying the parametric dissipation operation sets or resets a computational state of the at least one of the one or more qubit devices to the target state with a probability corresponding to the estimated value of the dissipation rate parameter.

3. The method of claim 1, wherein obtaining the estimated value of the dissipation rate parameter comprises obtaining the estimated value of the dissipation rate parameter from the computer program.

4. The method of claim 1, comprising:
obtaining information about an stochastic effect and a target value of the dissipation rate parameter,
wherein the computer system comprises a compiler, and obtaining the estimated value of the dissipation rate parameter comprises computing the estimated value of the dissipation rate parameter according to the target value of the dissipation rate parameter by operation of the compiler, and the parametric dissipation operation is configured to approximate the stochastic effect.

5. The method of claim 1, wherein the computer program is a hybrid classical-quantum program comprising classical computing operations and quantum computing operations, executing the computer program in the computer system comprises executing the classical computing operations on at least one classical processing unit, and obtaining the estimated value of the dissipation rate parameter comprises computing the estimated value of the dissipation rate parameter based on an output of the classical computing operations.

6. The method of claim 1, wherein executing the computer program in the computer system comprises executing a variational quantum algorithm comprising a quantum circuit ansatz and a classical optimization process, and executing the variational quantum algorithm comprises iteratively:
generating a parameter set for an iteration of the variational quantum algorithm, wherein the parameter set is generated based on one or more classical processing units executing the classical optimization process;
parameterizing the quantum circuit ansatz according to the parameter set for the iteration, wherein parameterizing the quantum circuit ansatz comprises determining the estimated value of the dissipation rate parameter; and
executing the parameterized quantum circuit ansatz on the quantum processing unit, wherein executing the parameterized quantum circuit ansatz comprises applying the parametric dissipation operation.

7. The method of claim 6, wherein parameterizing the quantum circuit ansatz comprises obtaining parameters for the quantum logic gate, and executing the quantum circuit ansatz comprises applying the parameterized quantum logic gate.

8. The method of claim 1, wherein the quantum processing unit comprises coupler devices coupled to the qubit devices, each coupler device comprises a dissipation element, and applying the parametric dissipation operation comprises:
generating dissipation drive signals for the coupler devices based on the estimated value of the dissipation rate parameter; and
communicating the dissipation drive signals to the coupler devices.

9. The method of claim 8, wherein the coupler devices are first coupler devices, the quantum processing unit comprises second coupler devices coupled to the qubit devices, the dissipation drive signals are first dissipation drive signals each coupler device comprises no dissipation element, and applying the quantum logic gate comprises:
generating coupler flux control signals for the second coupler devices;
communicating the coupler flux control signal to the second coupler devices;
generating second dissipation drive signals for the first coupler devices to deactivate the first coupler devices; and
communicating the second dissipation drive signals to the first coupler devices.

10. The method of claim 8, wherein the dissipation elements comprise ohmic dissipation elements.

11. The method of claim 10, wherein each ohmic dissipation element comprises a transmission line communicably coupled between the coupler device and an attenuator device.

12. The method of claim 8, wherein the coupler devices comprise resonator devices.

13. The method of claim 8, wherein each of the coupler devices comprise a tunable-frequency coupler device comprising a superconducting circuit loop with two Josephson junctions connected in parallel, and the dissipation element is an ohmic dissipation element in parallel with the two Josephson junctions.

14. The method of claim 8, wherein the quantum processing unit is a superconducting quantum processing unit, and the coupler devices are capacitively coupled to the qubit devices.

15. The method of claim 8, wherein the qubit devices comprise a first qubit device and a second qubit device communicably coupled to the first qubit device through a common coupler device, the parametric dissipation operation comprises a first control operation applied to the common coupler device, and the first control operation is configured to control application of the parametric dissipation operation to the first and second qubit devices.

16. The method of claim 15, wherein a programmable dissipation rate of the parametric dissipation operation applied to the first and second qubit devices is greater than or equal to an (Original) indirect qubit-qubit coupling rate between the first and second qubit devices.

17. The method of claim 1, wherein executing the computer program comprises preparing the qubits in an initial state defined by the computer program, and preparing the qubits in the initial state comprises applying the parametric dissipation operation.

18. A computer system, comprising:
a quantum processing unit comprising qubit devices; and
a control system, communicably coupled to the quantum processing unit, the control system configured to:
execute the computer program in the computer system, wherein executing the computer program comprises:
applying a quantum logic gate associated with a unitary operation to qubits defined by the qubit devices;
obtaining an estimated value of a dissipation rate parameter;
applying a parametric dissipation operation to one or more of the qubit devices, wherein the parametric dissipation operation has a programmable dissipation rate that is controlled by the estimated value of the dissipation rate parameter, the parametric dissipation operation being applied separately from the quantum logic gate; and
measuring a state of one or more of the qubit devices.

19. The computer system of claim 18, wherein the control system is configured to:
obtaining information about a target state of at least one of the one or more qubit devices,
wherein applying the parametric dissipation operation sets or resets a computational state of the at least one of the one or more qubit devices to the target state with a probability corresponding to the estimated value of the dissipation rate parameter.

20. The quantum computing system of claim 18, wherein obtaining the estimated value of the dissipation rate parameter comprises obtaining the estimated value of the dissipation rate parameter from the computer program.

21-34. (canceled)
